(19) United States
(12) Patent Application Publication
(10) Pub. No.: US 2026/0149459 A1
(43) Pub. Date: May 28, 2026

(54) HYBRID ANALOG-TO-DIGITAL CONVERSION DEVICE, METHOD, AND SENSOR SIGNAL PROCESSING DEVICE INCLUDING THE SAME

(71) Applicant: ELSSEN CO., LTD., Daejeon (KR)

(72) Inventor: Jiman PARK, Daejeon (KR)

(21) Appl. No.: 19/335,451

(22) Filed: Sep. 22, 2025

(30) Foreign Application Priority Data
Nov. 26, 2024 (KR) 10-2024-0171101
Mar. 5, 2025 (KR) 10-2025-0028385

(51) Int. Cl. H03M 1/46

(52) U.S. Cl. CPC H03M 1/462

(57) ABSTRACT

Provided are a hybrid analog-to-digital conversion device, method, and a sensor signal processing device including the same. The hybrid analog-to-digital conversion device refers to a hybrid analog-to-digital converter device for generating N-bit digital output (N≥1, natural number) may include a control-logic circuit, n comparators (n≥1, natural number), and a reference voltage generation circuit, and the control-logic circuit may control the reference voltage generation circuit according to the comparison result of the comparator to adjust the reference voltage or the input signal voltage that is applied to a single comparator or applied to at least one comparator among a plurality of comparators.

### CROSS-REFERENCE TO RELATED APPLICATION(S)

This application claims priority to Korea Patent Application No. 10-2024-0171101, filed on Nov. 26, 2024, and Korea Patent Application No. 10-2025-0028385, filed on Mar. 5, 2025, the entire contents of which are incorporated by reference in their entirety.

### FIELD OF THE INVENTION

The present invention relates to an analog-to-digital converter (ADC) for converting an analog voltage to a digital signal, and more particularly, to novel hybrid ADC technology that overcomes high-resolution implementation limitation found in the existing high-speed flash ADC and enables conversion and processing at once like the flash ADC without a multi-step procedure as in a successive approximation register (SAR) method.

### DESCRIPTION OF THE RELATED ART

An analog-to-digital converter (ADC) is widely used to digitize an analog signal generated by a sensor or a measurement target at consistent resolution. In general, the ADC samples continuous physical quantity, such as voltage or current, at regular time intervals and quantizes the same to a digital value for processing. This ADC technology has played a core role in various electronic systems, and various structures have been developed depending on a required resolution and speed.

The conventional ADC structure is broadly divided into a flash ADC method and a success approximation register (SAR) ADC method. A flash ADC has the advantage of being able to acquire digital signals very quickly with one-time sampling by arranging a plurality of comparators in parallel and is widely used in the field that requires ultra-high-speed computation, such as communication and video processing. However, according to an increase in resolution, 2^{N} to 1 comparators are required. Therefore, for example, 1,023 comparators need to be used to implement 10-bit resolution. This significantly increases a chip area and power consumption as well as complexity of a reference voltage generation circuit. In particular, when high bit counts are required, an even very small reference voltage needs to be generated, which makes the circuit design more challenging.

In contrast, an SAR ADC is in a structure of using a single comparator to adjust a reference voltage and compare the same with an input signal in a stepwise manner. This approach simplifies implementation and is advantageous in terms of miniaturization and power saving due to its small number of comparators. However, since each bit needs to be sequentially determined, a conversation speed is relatively slow compared to the flash ADC. Also, when implementing a high-resolution ADC, the reference voltage needs to be generated and controlled with great precision, which leads to increasing a circuit complexity and limiting a conversion speed.

As described above, since the flash ADC and the SAR ADC have limitations in simultaneously implementing a high speed and a high resolution, respectively, hybrid ADC research has been conducted to combine advantages of both methods. However, most of hybrid ADCs proposed in the past still have disadvantages of high hardware complexity and high power consumption, such as sequentially going through a plurality of steps or internally including a complex ADC module. In particular, in a high-resolution region in which resolution exceeds 12 bits, accurately generating an extremely small reference voltage unit and stably comparing the same has been a challenging task in all of flash ADC, SAR ADC, and simple hybrid structures. For example, in the case of a 24-bit ADC with the reference voltage V_{REF} of 1V, a least significant bit needs to accurately determine a very small voltage of about 1/16,777,216 V, making it susceptible to noise and requiring extremely strict control in a manufacturing process.

Due to this reason, there has been a persistent need for a novel ADC structure that may implement a higher resolution and, at the same time, support high-speed processing while using the small number of comparators. There is a need for a hybrid ADC design method that simultaneously satisfies high-speed and high-resolution conversion with low power consumption and low area by actively controlling the reference voltage or input signal voltage according to each comparison step while maintaining advantages of the parallel structure. In fact, research is being conducted on a new architecture that may dramatically reduce the number of comparators and power consumption compared to the existing flash ADC, may mitigate the speed constraints of the SAR ADC, and may lower the design difficulty even at high resolution.

Meanwhile, there is a need for improvement in digital conversion of a sensor signal. A conventional sensor signal processing device mainly employs a method of acquiring a digital value by converting resistance or capacitance change of a sensor into the form of a pulse width and by counting a time corresponding to the pulse width. However, this pulse width-measurement method requires a time delay and a counter operation to generate the pulse width, so has limitations in that the overall conversion speed is slow and inefficient. Therefore, a need for an ADC structure that may quickly digitize an analog signal acquired from a sensor without an additional complex operation is also emerging.

The background art described above is technical information that the inventor possessed for the purpose of deriving the invention or acquired in the deriving process of the present invention, and cannot necessarily be considered as publicly known technology disclosed to the general public prior to the application of the present invention.

### SUMMARY OF THE INVENTION

An objective of an example embodiment is to provide a hybrid analog-to-digital converter (ADC) device and method that may significantly reduce the number of comparators and may achieve low power consumption, miniaturization, and design simplification by merging step-by-step comparison and control-logic methods of a success approximation register (SAR) ADC into parallel or serial and parallel, while securing a fast conversion speed of a flash ADC level.

An objective of an example embodiment is to provide an ultra-high-resolution hybrid ADC device and method that is difficult to implement using a general SAR method by dividing an input signal voltage or a reference voltage into a plurality of groups and controlling the same or by transforming and repeatedly comparing the input signal voltage itself in order to enable stable reference voltage generation even at high resolution.

An objective of an example embodiment is to provide a sensor signal processing device that may directly convert an analog signal acquired from a change in resistance or capacitance of a sensor to a digital signal at high speed without additional time delay by simplifying a sensor interface.

The objectives of example embodiments are not limited to tasks described above and other objectives and advantages not described herein may be understood by the following description and will be more clearly understood by the example embodiments. Also, it will be appreciated that the objectives and the advantages of the present invention may be achieved by the methods and combinations thereof set forth in the claims.

A hybrid analog-to-digital conversion device according to an example embodiment refers to a hybrid analog-to-digital converter device for generating N-bit digital output (N≥1, natural number) and may include a control-logic circuit; n comparators (n≥1, natural number) each configured to compare an input signal voltage (V_{A}) and a reference voltage and to generate comparison output; and a reference voltage generation circuit configured to provide the preset reference voltage to the comparator, and the control-logic circuit may control the reference voltage generation circuit according to the comparison output of the comparator to adjust the reference voltage or the input signal voltage (V_{A}) that is applied to a single comparator or applied to at least one comparator among a plurality of comparators.

In addition, a computer-readable recording medium storing a computer program to execute other methods, other systems, and the method for implementing the present invention may be further provided.

Other aspects, features, and advantages other than those described above will become apparent from the following drawings, claims, and detailed description of the present invention.

According to example embodiments, a hybrid ADC has the effect that it is possible to achieve high resolution by dramatically reducing the large number of comparators required in a flash structure while maintaining a fast conversion speed of the conventional flash ADC. For example, based on 10 bits, the conventional flash ADC requires 1,023 comparators, but the present invention may perform 10-bit conversion only with ten comparators and thus, may significantly reduce a chip area and power consumption. Therefore, by combining the high speed of flash with the power and area efficiency of SAR and by achieving precision and noise averaging aspects provided by a double integration method in a single architecture, it is possible to mitigate the constraints of having to select a different ADC for each usage and to cover the wide range of needs with a single hybrid ADC.

Also, a hybrid ADC according to an example embodiment has the effect of being able to perform stable and practical voltage comparison even in an ultra-high-resolution region of 24 bits or more by applying a parallel group method or an input signal voltage transformation method. That is, by dividing an input signal or a reference voltage into a plurality of steps and thereby controlling the same, it is possible to implement ADC operation even at ultra-high resolution that is difficult to implement with a general SAR structure. In particular, according to an example embodiment, it is possible to efficiently segment and generate a reference voltage, so noise sensitivity issues according to reference voltage segmentation occurring at high resolution may be mitigated. This may indicate that it may be practically applied even in the precision measurement field in which a conventional double integration (dual-slope) method is mainly used.

In addition, a hybrid ADC according to an example embodiment has the effect of being able to flexibly optimize the design according to required resolution (number of bits), speed, power consumption, and the like by integrally providing various hybrid structures (parallel, serial, parallel-serial hybrid, cyclic, etc.) that combine advantages of flash and SAR. For example, an interface between a comparator and a control-logic circuit is simplified, which may significantly reduce complex reference voltage distribution and noise issues that have been problems in the conventional high-resolution ADC design. Also, according to a decrease in the number of comparators, circuit resources may be saved and the design difficult may also be reduced, and stable performance may be achieved even when implementing a high number of bits.

Further, while one of flash, SAR, and double integration conventionally needs to be selected and individually designed depending on application service requirements (speed, resolution, power, noise immunity), the present invention may cover different requirement levels with a single ADC platform by selecting a parallel operation, a cyclic operation, or a serial and parallel mixed operation. This not only reduces a chip area and power consumption according to a reduction in the number of comparators, but also manages reference voltage distribution and noise vulnerability issues during high-resolution implementation within a consistent structure.

A hybrid ADC according to an example embodiment may meet the needs of the field that simultaneously requires both a high resolution and a high speed, such as high-speed signal processing, artificial intelligence (AI) computing, and an image sensor. Even in a system that requires complex computation or deep neural network processing, the ADC of the present invention provides high-performance analog-to-digital conversion with low power consumption and a small area, and thus may be easily integrated into the system.

Also, a sensor interface combination form according to an example embodiment may directly digitally convert a sensor output signal without a separate time delay, thereby improving a sensor signal processing speed. Compared to indirect conversion methods, such as conventional pulse width measurement, the example embodiment has the advantage of acquiring sensor data in near real time by directly inputting a voltage acquired from a sensor to an ADC for processing.

The effects of the present invention are not limited to those described above and other effects not described will be clearly understood by those skilled from the following description.

### BRIEF DESCRIPTION OF DRAWINGS

These and/or other aspects, features, and advantages of the invention will become apparent and more readily appreciated from the following description of embodiments, taken in conjunction with the accompanying drawings of which:

FIG. 1 schematically illustrates a basic operation structure of a flash analog-to-digital converter (ADC) and a success approximation register (SAR) ADC;

FIG. 2 illustrates the entire configuration of a parallel hybrid ADC that combines advantages of a flash ADC and a SAR ADC according to an example embodiment;

FIGS. 3 to 5 illustrate three reference voltage generation methods available when implementing the parallel hybrid ADC of FIG. 2; FIG. 3 exemplifies a current source-based method, FIG. 4 exemplifies a resistance voltage division method, and FIG. 5 exemplifies a method using a capacitor, respectively;

FIGS. 6 to 8 illustrate one method of designing a reference voltage in a stepwise manner from a most significant bit (MSB) to a least significant bit (LSB) using an 8-bit ADC as an example by employing a reference voltage generation method of FIG. 2; FIG. 6 illustrates an upper 4-bit generation unit, FIG. 7 illustrates an intermediate 2-bit generation unit, and FIG. 8 illustrates a lower 2-bit generation unit, respectively;

FIG. 9 is a graph showing a process of simultaneously comparing the reference voltages from the MSB to the LSB according to FIGS. 6 to 8 with an input signal voltage on a time axis, and represents an exemplary operation flow in which the result of each comparison is immediately reflected to determine a reference voltage of next comparison;

FIG. 10 schematically illustrates circuit examples of generating the reference voltage in FIG. 9; (a) illustrates a current-based resistance control circuit, (b) illustrates a resistance-based current control circuit, and (c) illustrates a capacitor-based current control circuit;

FIG. 11 illustrates the process of FIGS. 6 to 8 in a flowchart form in which the process proceeds in a stepwise manner from MSB comparison to LSB comparison in a parallel hybrid ADC, and the result of each comparison is immediately reflected to comparison of a next step;

FIG. 12 illustrates a parallel-group hybrid ADC configuration for achieving high resolution by dividing a parallel hybrid ADC structure into a plurality of groups;

FIGS. 13 and 14 illustrate a method of transforming and comparing an input signal voltage (V_{A}) for high resolution, and an input signal voltage generation circuit for implementing ultra-high resolution, respectively;

FIG. 15 is a conceptual diagram of a serial cyclic hybrid ADC, and illustrates an operation of performing comparison at each step by fixing a reference voltage to ½ V_{REF} and by transforming an input signal voltage in a stepwise manner;

FIG. 16 illustrates an example showing how input voltage is transformed for each step for examples (e.g., 0.46 V, 0.94 V, etc.) of an actual input signal voltage with respect to the cyclic hybrid ADC of FIG. 15; (a) and (b) of FIG. 16 exemplify a process of generating a next step input voltage according to deformation formula and a process of comparing the same, respectively;

FIG. 17 illustrates a step-by-step voltage transformation process in another form for an example of an actual input signal voltage in the cyclic hybrid ADC of FIG. 15, and FIG. 16 and FIG. 17 complementarily describe the operating principle of the cyclic ADC;

FIG. 18 illustrates an example of circuits that generate an input signal voltage within the parallel hybrid ADC of FIG. 2 and the cyclic hybrid ADC of FIG. 15 in which circuit implementation examples of generating input signals in different ADC structures are compared;

FIG. 19 illustrates a parallel-cyclic hybrid ADC configuration that combines the parallel hybrid ADC method of FIG. 2 and the cyclic hybrid ADC method of FIG. 15;

FIGS. 20 to 23 illustrate circuit examples for applying an input signal voltage generation method of FIG. 14 to a group-hybrid ADC; FIG. 20 illustrates an example of using an instrumentational amplifier, FIG. 21 illustrates an example of using an OP amplifier buffer and a differential amplifier, FIG. 22 illustrates an example of using an operational transconductance amplifier (OTA) and a current mirror, and FIG. 23 illustrates an example of using a dual OTA and a current mirror;

FIGS. 24 and 25 illustrate different implementation examples of a circuit that generates the input signal voltage in the cyclic hybrid ADC of FIG. 17; FIG. 24 illustrates an example of applying a cyclic sample-and-hold circuit, and FIG. 25 illustrates an example of an input voltage generation circuit that includes sample-and-hold (S&H);

FIGS. 26 to 31 illustrate various implementation examples of the input signal voltage generation circuit of FIG. 18; FIG. 26 illustrates an example of using two OTAs, FIGS. 27 and 28 illustrate an example of using two OTAs and a current mirror, FIG. 29 illustrates an example of using a single OTA, a current mirror, and an OTA-resistor combination, FIG. 30 illustrates an example of using an OP amplifier-based instrumentational amplifier, and FIG. 31 illustrates an example of using an OP amplifier buffer and a differential amplifier;

FIG. 32 is a block diagram illustrating a sensor signal processing configuration in which a single resistive sensor and a hybrid ADC are connected;

FIG. 33 illustrates the block configuration of FIG. 32 at the circuit level in detail;

FIG. 34 is a block diagram illustrating a sensor signal processing configuration in which a single capacitive sensor and a hybrid ADC are connected;

FIG. 35 illustrates the configuration of FIG. 34 at the circuit level in detail;

FIG. 36 is a block diagram illustrating a sensor signal processing configuration connected to a hybrid ADC using a plurality of resistive sensors and a differential amplifier;

FIG. 37 is a block diagram illustrating a sensor signal processing configuration connected to a hybrid ADC using a plurality of capacitive sensors and a differential amplifier;

FIG. 38 is a configuration diagram illustrating a detailed example of generating an input signal voltage using an OTA and a fixed resistor in the configuration of FIG. 36;

FIG. 39 is a configuration diagram illustrating a detailed example of generating an input signal voltage using an OTA and a fixed capacitor in the configuration of FIG. 36;

FIG. 40 is a configuration diagram illustrating a detailed example of generating an input signal voltage using an OTA and a fixed resistor in the configuration of FIG. 37;

FIG. 41 is a configuration diagram illustrating a detailed example of generating an input signal voltage using an OTA and a fixed capacitor in the configuration of FIG. 37;

FIG. 42 illustrates a detailed circuit diagram for the configuration of FIG. 38;

FIG. 43 illustrates a detailed circuit diagram for the configuration of FIG. 39;

FIG. 44 illustrates a detailed circuit diagram for the configuration of FIG. 40; and FIG. 45 illustrates a detailed circuit diagram for the configuration of FIG. 41.

### DETAILED DESCRIPTION OF THE INVENTION

Hereinafter, example embodiments will be described with reference to the accompanying drawings. The drawings are provided as examples only to help understanding and the present invention is not limited thereto and some configurations may be exaggerated to clearly describe the gist.

Unless otherwise defined, technical and scientific terms used herein are used in their usual sense, and detailed description related to the known functions and configurations will be omitted within the range of not detracting from essence of the invention. Also, the technical information acquired in the process of deriving the invention may be included in the described background technology, but it is not necessarily interpreted as publicly known art prior to filing. If necessary, the known structure is omitted or a block diagram that focuses on core functions is illustrated to help understanding.

Herein, the terms, “comprises/includes” and the like, are open-ended and do not preclude elements, materials, and processes that are not listed, and the singular forms include the plural forms as well.

The present invention relates to an analog-to-digital converter (ADC) and proposes a hybrid structure that combines the high speed of a flash ADC and the efficiency of a success approximation register (SAR) ADC. The flash ADC is fast, but requires 2^{N-1} (e.g., 1,023 for 10 bits) comparators when implementing high resolution, thereby increasing area and power consumption, and generating very small reference voltage. Therefore, design complexity and noise issues also increase. In comparison, the present invention may save an area and power consumption by aiming for the flash-level speed, while reducing the area while reducing the number of comparators to N (e.g., 10 for 10 bits) at the same resolution.

The SAR ADC is low-power, but requires the precise reference voltage (2ⁿ scale) for each step. The present invention overcomes the limitations by utilizing a SAR control logic and, here, by selectively controlling not only the reference voltage but also the input signal voltage itself. As a result, through various hybrid configurations, such as parallel configuration or serial-parallel mixed configuration of flash and SAR, the high speed and the high resolution may be simultaneously secured while simplifying the circuit and achieving the low power consumption.

The proposed structure encompasses both (i) a method of fixing the input voltage and generating the reference voltage in a stepwise manner, and (ii) a method of fixing the reference voltage (e.g., ½ V_{REF}) and transforming the input voltage for repeated comparison. Through this, degradation in accuracy due to minimization of the reference voltage may be mitigated in conjunction with a control logic even at high resolution of 12 bits or more and even 24 bits or more. Also, by utilizing the step-by-step comparison principle of SAR in parallel while maintaining fast conversion characteristic of flash, the proposed structure may be flexibly applied from 10 bits to 24 bits or more.

A reference voltage generator (digital-to-analog converter (DAC)) of the present invention may be selectively applied according to process and system requirements among various methods such as a current-based resistor, a capacitor, and the like, thereby providing high design flexibility and expandability. Since stable comparison is possible even at ultra-high resolution through an overlap and repetition control technique, it may be easy to realize an ADC of 24 bits or more, which was difficult to implement in the art. Therefore, it provides area and power advantages in terms of a portable device, high-speed signal processing, and large-scale parallel operation.

Also, the hybrid ADC of the present invention is easily applied to a sensor signal processing circuit that directly digitizes a change in resistance or capacitance of a sensor. The conventional pulse width conversion and counter method has a large response delay, but the present invention may immediately convert to the hybrid ADC if a voltage signal (V_{IN}) is formed through sample-and-hold (S/H), thereby enabling high-speed response. That is, by generating the input voltage V_{IN} and by adding the same to the ADC of the present invention, digital output may be quickly acquired without an additional conversion process.

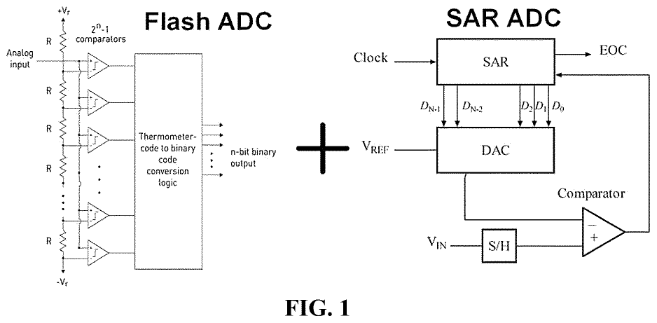

FIG. 1 schematically illustrates a basic operation structure of a flash ADC and a SAR ADC.

FIG. 1 comparatively illustrates the structure of the flash ADC and the structure of the SAR ADC. Since the flash ADC simultaneously compares an input analog signal with a plurality of reference voltages by arranging a plurality of comparators in parallel, digital output is acquired in one cycle. On the other hand, the SAR ADC sequentially determines bits from a most significant bit (MSB) to a least significant bit (LSB) using a single comparator, and performs conversion over a plurality of cycles by adjusting the reference voltage of a DAC based on the previous comparison result. The present invention proposes a new structure that effectively combines two methods.

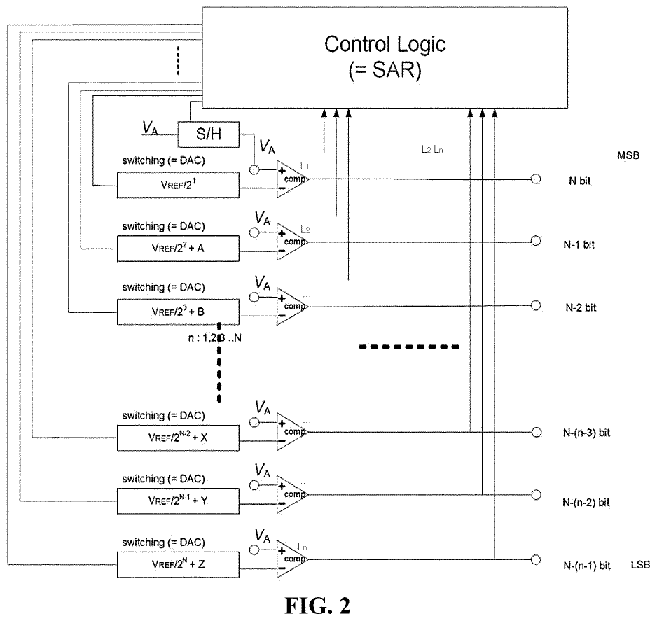

FIG. 2 illustrates the entire configuration of a parallel hybrid ADC that combines advantages of a flash ADC and a SAR ADC according to an example embodiment.

FIG. 2 illustrates a structure of a hybrid ADC according to an example embodiment. This structure may quickly perform signal processing from an MSB to an LSB and may flexibly implement the resolution from 4 bits to 24 bits, for example. The operation proceeds in such a manner that the MSB is determined through comparison between an input voltage (V_{A}) and ½ V_{REF} and a control logic determines a reference voltage of a next step (MSB-1) based on the result. Then, the entire N-bit section is sequentially performed by reflecting the comparison result of each s and by continuously setting the reference voltage of the next step, and the overall conversion delay may be reduced through an asynchronous control.

The hybrid ADC may include a control logic (e.g., SAR logic), a comparator array, a reference voltage generation circuit, and a sample-and-hold (S/H). In some examples, the comparator array may include a plurality of comparators L₁ to Lₙ, and the reference voltage generation circuit may include a step-by-step reference voltage generation unit.

The control logic receives output of each comparator and immediately determines the reference voltage of the next step. The comparators are arranged in parallel and each comparator compares the applied reference voltage with V_{A} and outputs “1” or “0”. The reference voltage generation circuit is implemented in a DAC structure using a resistor, a capacitor, and a current source, and the step-by-step reference voltage generation unit provides a reference voltage suitable for a comparator of a corresponding step. The reference voltage is based on a fractional value of V_{REF} (e.g., ½ V_{REF}, ¼ V_{REF}, ¾ V_{REF}), and uses the form of V_{REF}×(integer/2ⁿ) according to the binary search principle. If necessary, an offset may be added to correct a comparator error or DAC imbalance.

The S/H samples V_{A} at the start of conversion and maintains the same until conversion is completed, thereby suppressing an error due to input fluctuation and ensuring that all comparators make stable decision based on the same input.

In short, the example embodiment sets a next reference voltage by starting with comparison between V_{A} and ½ V_{REF} and by reflecting the result of each step in real time, and determines the digital output from an MSB to an LSB by repeating the procedure of comparing the corresponding reference voltage and V_{A} N times. By combining this step-by-step reference voltage setting and the parallel comparator structure, it is possible to suppress the number of comparators and to simultaneously achieve a high resolution and a fast conversion speed.

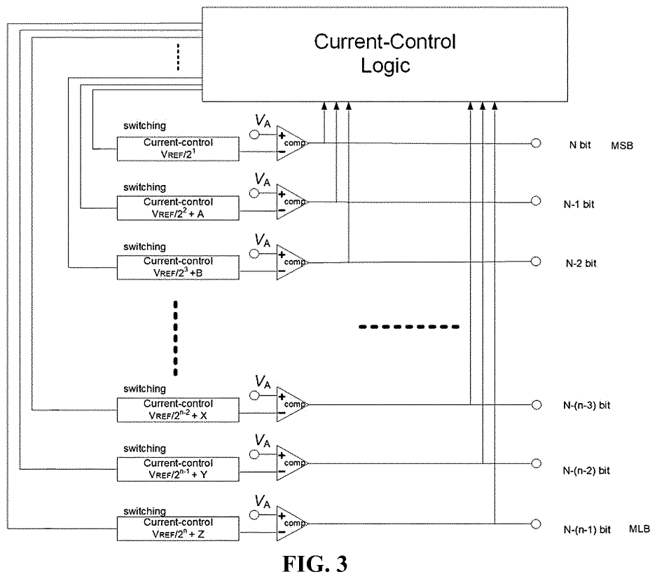

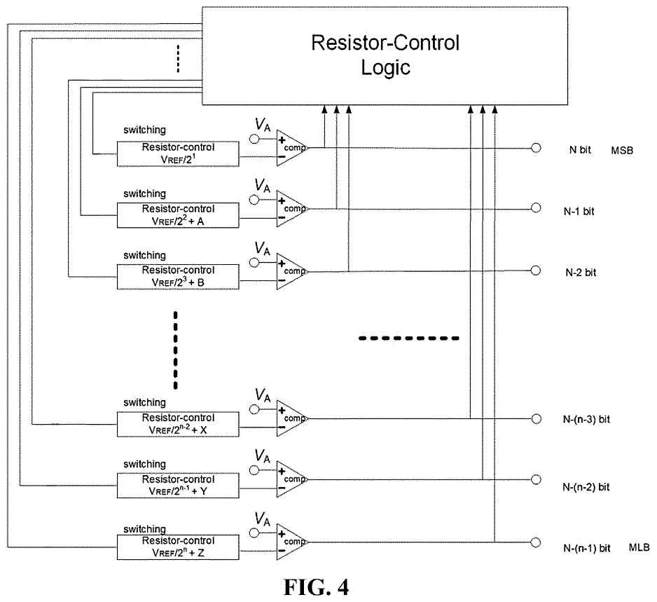

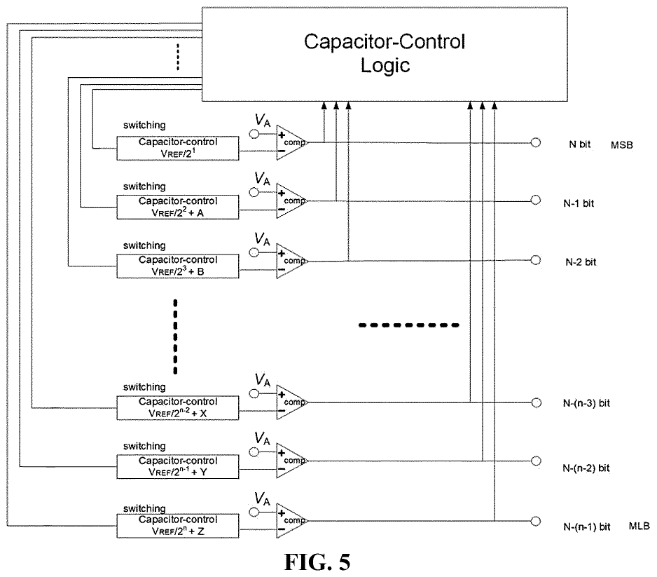

FIGS. 3 to 5 illustrate three reference voltage generation methods available when implementing the parallel hybrid ADC of FIG. 2. FIG. 3 exemplifies a current source-based method, FIG. 4 exemplifies a resistance voltage division method, and FIG. 5 exemplifies a method using a capacitor, respectively.

FIG. 3 forms a reference voltage by generating reference current using the current source-based method and by applying the same to a resistor. FIG. 4 acquires the reference voltage by selecting or switching a node voltage of a resistive voltage division network. FIG. 5 forms a reference voltage by charging or discharging a capacitor in advance or by dividing the capacitor. All three methods generate the step-by-step reference voltage for comparison with the input voltage (V_{A}) and supplies the same to the comparator, and circuit configuration, accuracy, and power characteristics may vary depending on implementation selection.

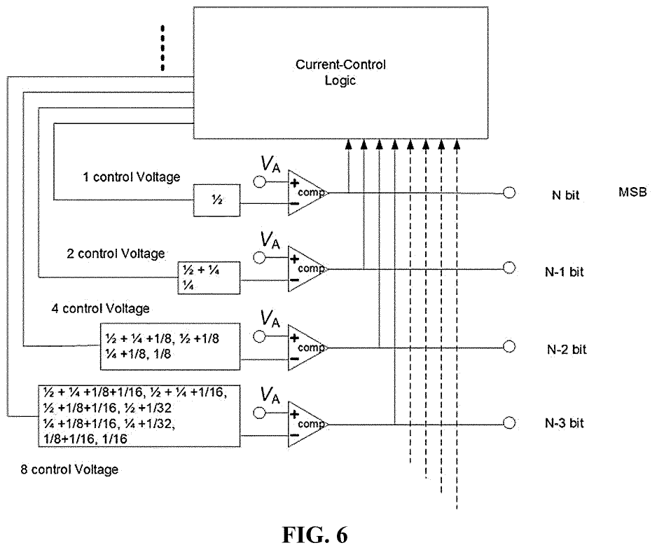

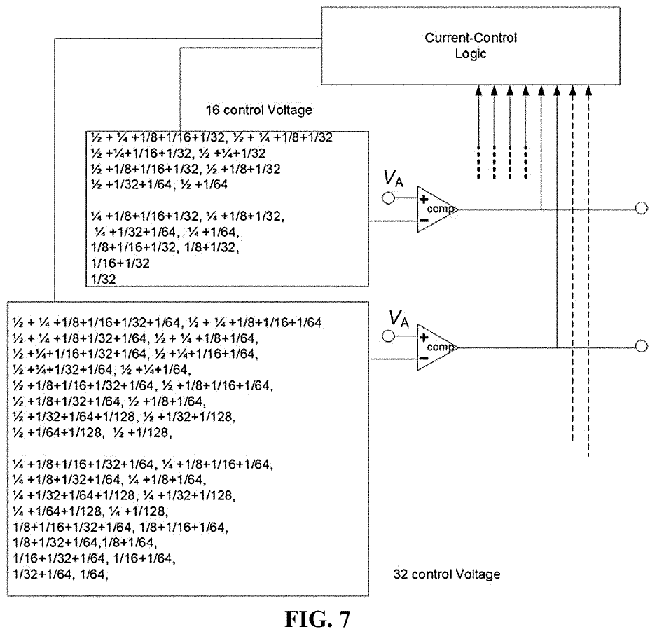

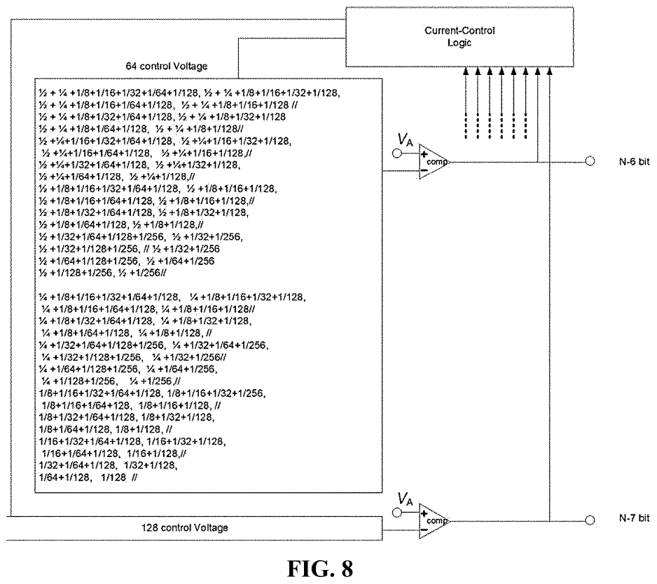

FIGS. 6 to 8 illustrate one method of designing a reference voltage in a stepwise manner from an MSB to an LSB using an 8-bit ADC as an example by employing a reference voltage generation method of FIG. 2. FIG. 6 illustrates an upper 4-bit generation unit, FIG. 7 illustrates an intermediate 2-bit generation unit, and FIG. 8 illustrates a lower 2-bit generation unit, respectively.

In this example, an MSB decision criterion is ½ V_{REF}. Once the MSB is determined through comparison with the input voltage V_{A}, the reference voltage of a next step is selected as ¼ V_{REF} Or ½ V_{REF}+¼ V_{REF} depending on the MSB result. In following next steps, one of V_{REF}× (integer/2^{k}) candidates is selected according to a binary search principle and compared with V_{A}. Although there are branching cases, only one reference voltage is actually used at each step. For example, if V_{A}<½ V_{REF}, MSB becomes 0 and the next reference voltage is ¼ V_{REF}, and MSB-1 is determined as a result of comparison. The result of each comparison is delivered to the control logic and the reference voltage generation circuit immediately generates the next step reference voltage.

As a result, this parallel hybrid ADC relates to the form that parallelizes the step-by-step comparison of SAR and combines a multi-comparison structure of flash, and simultaneously secures the high conversion speed and resolution while simplifying a circuit by quickly generating a different reference voltage and supplying the same to a comparator while fixing the input voltage.

FIG. 9 is a graph showing a process of simultaneously comparing the reference voltages from the MSB to the LSB according to the procedure of FIGS. 6 to 8 with the input signal voltage (V_{A}) on a time axis. The comparison result of each step is immediately delivered to the control logic to set a reference voltage of a next step, and a next comparison is asynchronously performed. The operation starts with comparison between V_{A} and ½ V_{REF} to determine the MSB and sets the reference voltage of MSB-1 based on the result. As this procedure sequentially proceeds in a stepwise manner, the next step starts immediately after each step is completed, so final N-bit digital output is quickly determined.

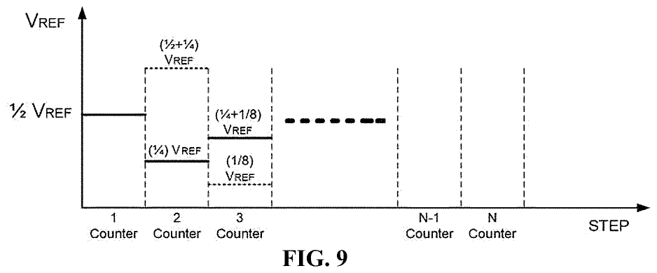

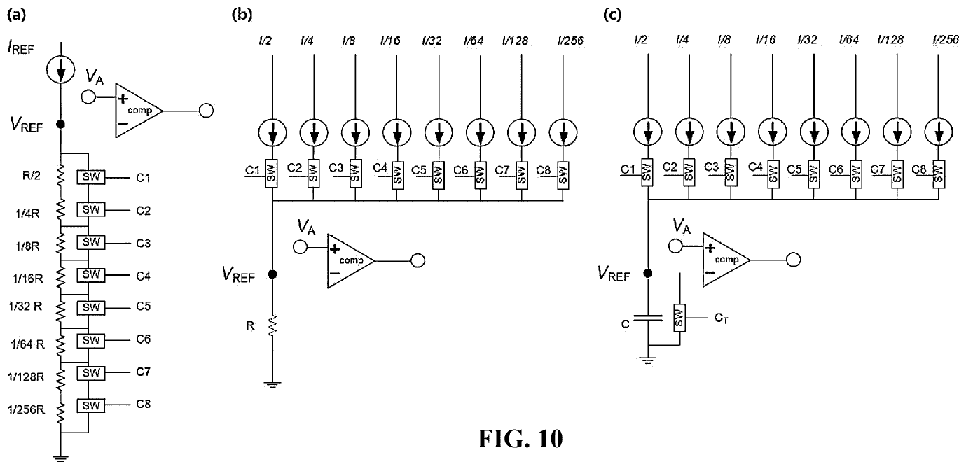

FIG. 10 illustrates examples of the reference voltage generation circuit used in FIG. 9, which may be implemented with (a) a current-based resistance control circuit, (b) a resistance-based current control circuit, and (c) a capacitor-based current control circuit. Such a circuit is a DAC and quickly generates a necessary reference voltage. For example, resistive voltage division forms ½ V_{REF} through switching and a current control method acquires a target voltage by simply adjusting a current size. The reference voltage may be implemented using combination of a current source and a resistor or a capacitor. If comparison is completed after charging, a capacitor method requires a reset to ensure accuracy of the next step. Various combinations of elements may quickly and accurately provide a reference voltage necessary for a comparator at each step.

FIG. 11 illustrates the process of FIGS. 6 to 8 in a flowchart form, that is, illustrates a flowchart of the parallel hybrid ADC. The input voltage (V_{A}) is maintained and only the reference voltage is adjusted in a stepwise manner, and the MSB comparison result is immediately reflected to settings of the next step and sequentially determined up to the LSB. The result of each step is reflected in real time, and comparison and reference voltage setting are continuously performed, so all N bits are quickly converted.

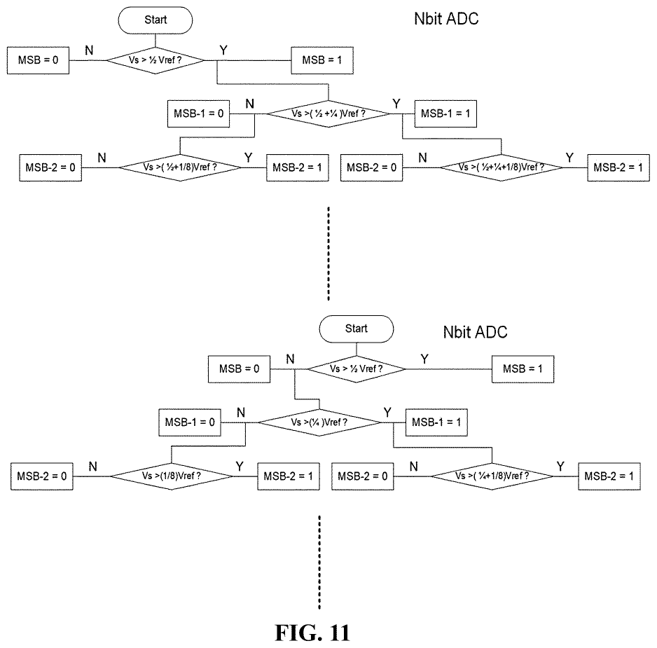

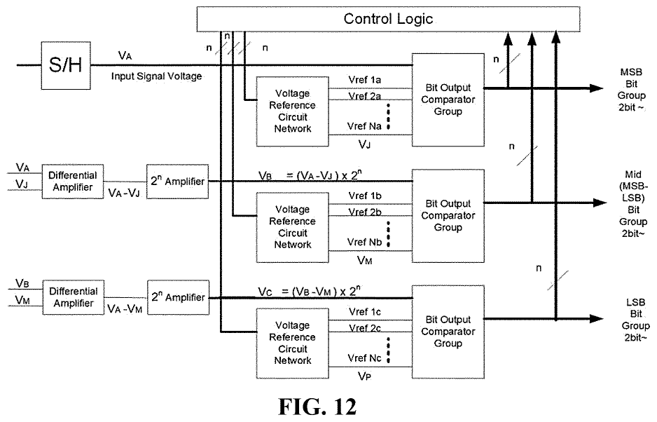

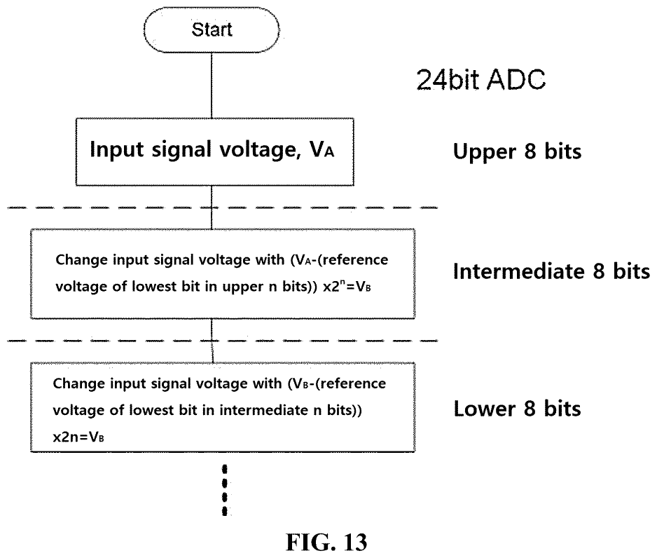

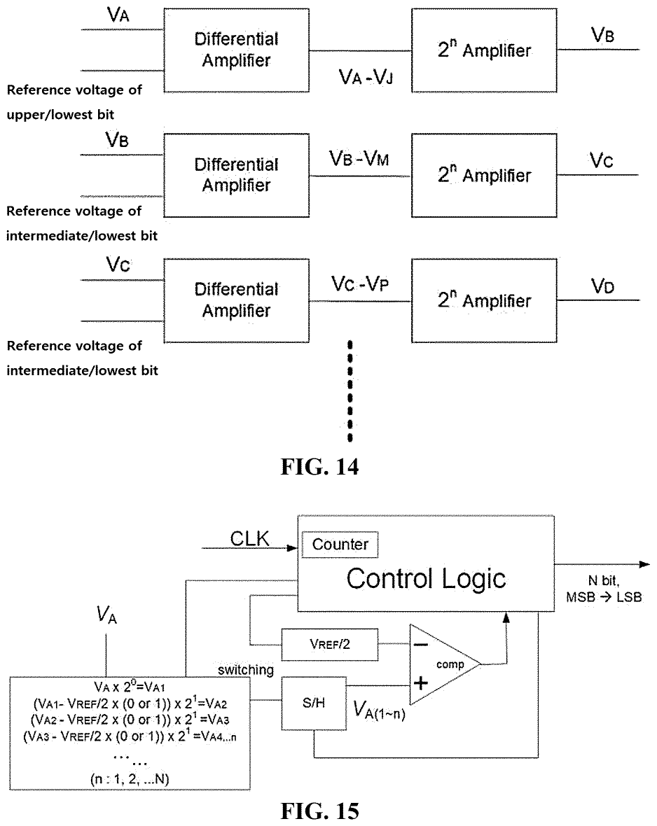

FIG. 12 illustrates a parallel-group hybrid ADC configuration that divides a comparator into a plurality of groups to achieve high resolution. FIG. 13 illustrates a method of transforming and comparing the input voltage (V_{A}) for high resolution, and FIG. 14 illustrates an example of an input voltage generation circuit. The method of FIG. 2 has the advantage of high speed, low area, and low power consumption, but has limitations since a very small reference voltage of V_{REF}/2^{N} level needs to be generated for 12 bits or more. For example, V_{REF}=1 V, 24-bit LSB is about 1/16,777,216 V, which is a noise level and difficult to practically implement.

Accordingly, the entire bits are divided into a plurality of groups and the same reference voltage range is repeatedly used within each group. For example, if 24 bits are divided into 3 groups of 8 bits each, the minimum reference voltage of each group is realistically 1/256 V_{REF} (about 3.9 mV). The group size may be selected from 2 to 8 bits, and may be expanded up to 12, 16, and 32 bits based on the sample principle. When the input voltage is not fixed, S/H is used to maintain V_{A} during conversion.

Also, a residual signal is scaled using the result of an upper group and used as input for a next group. After upper group conversion, the lowest bit reference voltage V_{J} of the corresponding group is subtracted from V_{A}, a subtraction result value is multiplied by 2^{K} (number of group bits), and a multiplication result value is set as the next group input V_{B}.

$$( {V}_{A} - {V}_{J} ) \times {2}^{K} = {V}_{B}$$

Similarly, high resolution is achieved by sequentially proceeding with lower groups, such as (V_{B}−V_{M})×2^{K}=V_{C}, (V_{C}−V_{P})×2^{K}=V_{D}. This method may be expanded up to 32 bits.

FIGS. 13 and 14 illustrate an input voltage transformation method. Based on the step-by-step comparison result, the corresponding reference voltage is subtracted from the input voltage, a subtraction result value is magnified by 2^{K}, and its result value is used as input for the next step. This method is reliably scalable to high resolution since precise control is required for only limited voltage range in each group. Also, the structures of FIGS. 2 to 14 asynchronously operate without an external clock to produce output bits, so are suitable to implement the high speed and the high resolution.

FIG. 15 is a conceptual diagram of a serial cyclic hybrid ADC, and illustrates a structure of sequentially determining N bits by repeatedly comparing the reference voltage with the transformed input voltage at each step in a state in which the reference voltage is fixed to ½ V_{REF}. Compared to the parallel method of FIG. 2, the proposed method has a long conversion time, but has low power consumption and may easily reduce circuit scale, so is suitable for high-resolution implementation. Input voltage transformation may be realized using the circuit based on the current source, the resistor, and the capacitor of FIGS. 3 to 5.

The operation determines the MSB by comparing the initial input V_{A} with ½ V_{REF} and then at each step k, updates the input to V_{{k+1}}=(Vₖ−bₖ× V_{REF}/2)×2 based on the previous comparison result bₖ and compares the same again with the same ½ V_{REF}. Here, bₖ is 0 or 1 depending on the comparison result of a corresponding step, and is sequentially confirmed up to LSB by repeating this process N times. Since a comparison threshold is constant at all steps, comparator requirements are simplified and there is no need to directly generate the reference voltage with very small resolution, so complexity and sensitivity of DAC are reduced.

For implementation, a sample-and-hold or an integral-type hold node are provided to stably deliver voltage between steps. For capacitor-based implementation, residual charge is removed through appropriate reset after each step is completed. A current-controlled or resistive voltage divisive circuit may implement step-by-step subtraction and gain multiplication through switching, and may compensate for a comparator offset and DAC imbalance with a correction signal of the control logic.

As a result, this cyclic structure significantly reduces the DAC burden and provides low-power, high-resolution conversion with less hardware by fixing the reference voltage and by updating only input.

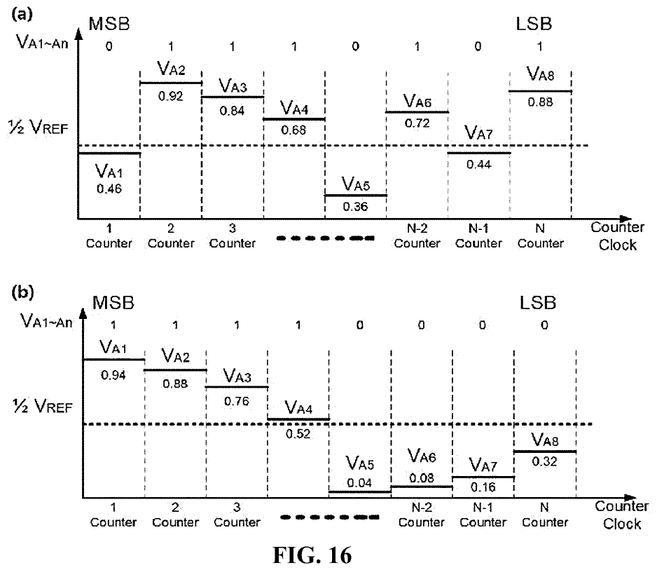

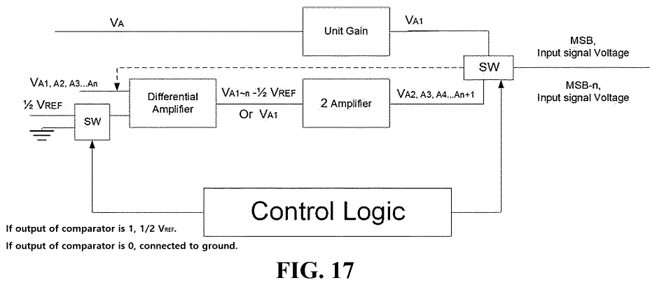

FIG. 16 illustrates step-by-step update of the input voltage in the cyclic hybrid ADC with example values (e.g., 0.46 V, 0.94 V, V_{REF}=1 V). (a) and (b) of FIG. 16 show a procedure of generating a next input at each step according to the rule of V₍ₖ₊₁₎={V₍ₖ₎−b₍ₖ₎× V_{REF}/2}× 2 and comparing the same with the same reference voltage (½ V_{REF}). FIG. 17 provides the same operation in different representation, and represents that the above computation may be implemented using a current source, a resistor, a capacitor, and switching. The operation determines the MSB by comparing the initial input voltage V_{A} and ½ V_{REF}, and performs sequential decision up to the LSB by repeating subtraction and multiplication according to the comparison result, that is, a value of b (k). This configuration stably achieves high-resolution conversion without directly generating the very small reference voltage.

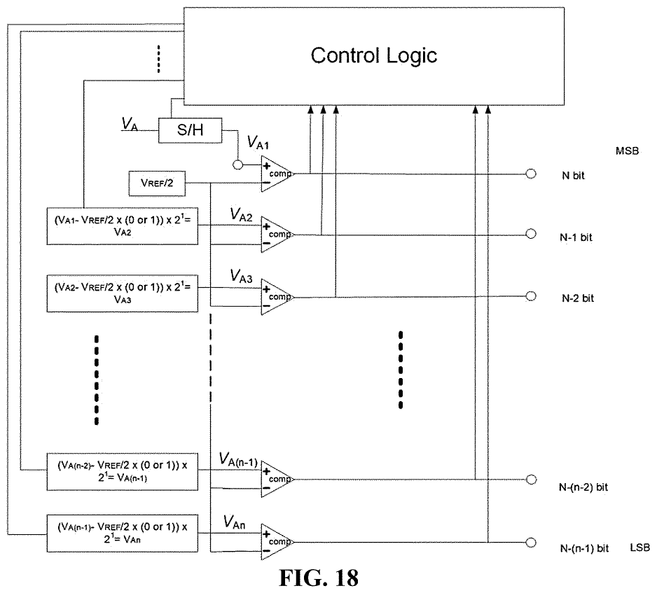

FIG. 18 illustrates an example of circuits that generate the input signal voltage in the parallel hybrid ADC of FIG. 2 and the cyclic hybrid ADC of FIG. 15 through comparison. Also, proposed is a parallel-cyclic hybrid ADC configuration that integrates the two methods, thereby simultaneously securing advantages of high speed of the parallel structure and low power consumption and high resolution of the cyclic structure. This configuration mitigates the difficulty in comparing ultra-low voltages during high-speed conversion, improves the problem pointed out in FIG. 1, and simplifies the circuit to reduce power consumption and implementation difficulty. In addition, depending on the required specifications, design expansion may be flexibly performed from low resolution of 2 bits or more to high resolution of 24 bits or more.

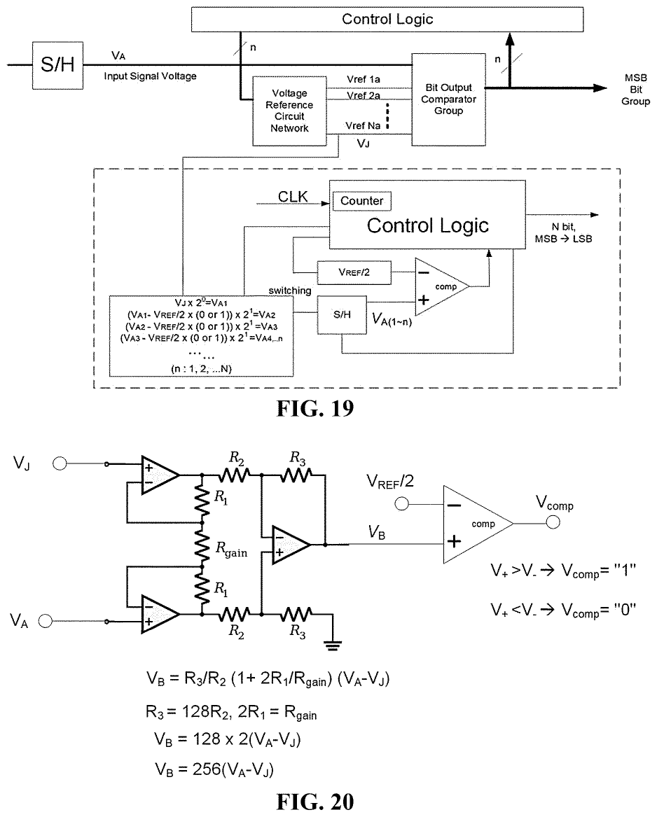

FIG. 19 illustrates a parallel-cyclic hybrid ADC configuration that combines the parallel hybrid ADC of FIG. 2 and the cyclic hybrid ADC of FIG. 15. This structure combines a parallel processing section and a cyclic processing section to maintain the high-speed operation, to reduce the number of comparators and the number of reference voltage generation circuits, and to reduce a circuit area and power consumption. Therefore, a high speed and a high resolution may be simultaneously achieved while reducing the overall complexity.

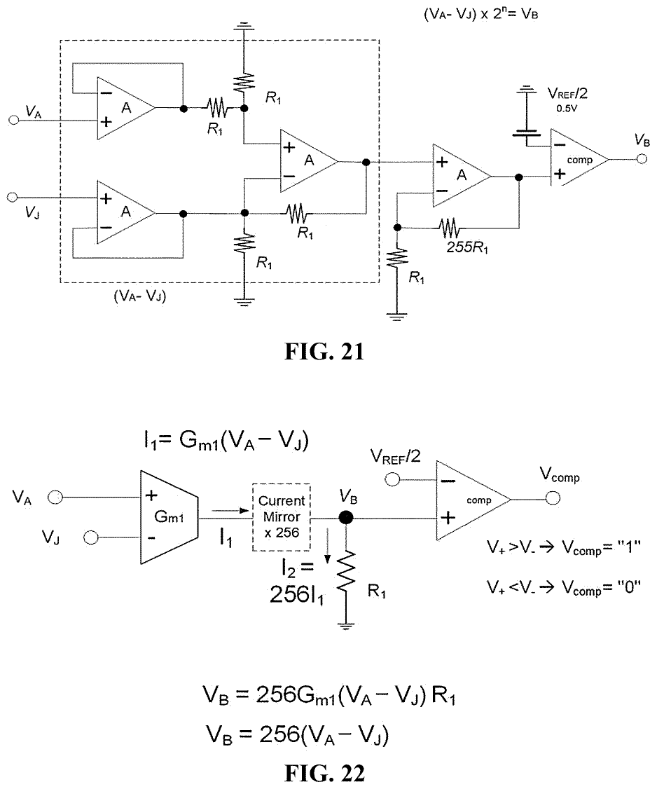

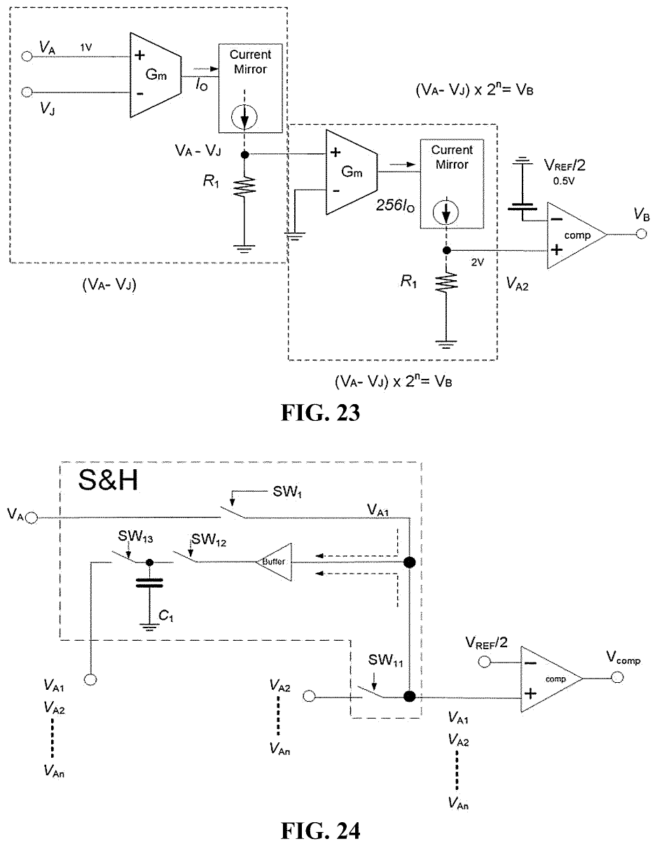

FIGS. 20 to 23 illustrate circuit examples for applying the input signal voltage generation method of FIG. 14 to a group-hybrid ADC. FIG. 20 is configuration based on an instrumentational amplifier, FIG. 21 is configuration based on an OP amplifier buffer and a differential amplifier, FIG. 22 is configuration based on an operational transconductance amplifier (OTA) and a current mirror, and FIG. 23 is configuration based on a dual OTA and a current mirror. FIG. 20 may be implemented using an OP amplifier or an OTA. OTA application has advantages in terms of simplicity and ease of implementation.

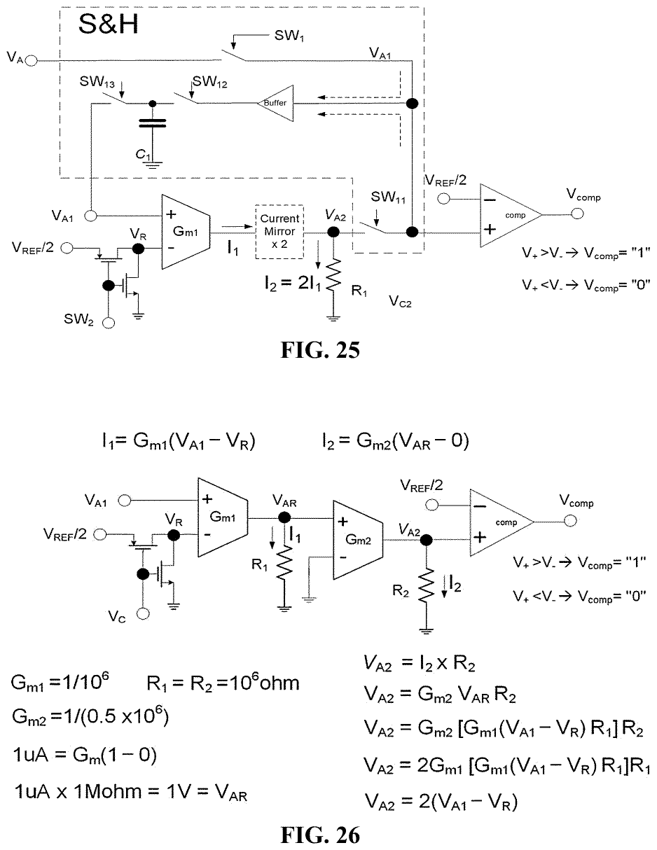

FIGS. 24 and 25 illustrate examples of simplified sample-and-hold (S/H) implementation that generates input voltage in the cyclic hybrid ADC of FIG. 17. In step 1, the external input V_{A} is applied as is to a comparator, and compared with V_{REF}/2 in a state in which SW₁ is turned on, SW₁₁ is turned off, and SW₁₂ and SW₁₃ are turned on, to determine the MSB.

After step 2, it is updated to V_{{k+1}}=Vₖ−bₖ×V_{REF}/2 based on the result of the previous step, bₖ (0 or 1), a multiplier (e.g., 2×) is applied if necessary, and a result value is compared again with V_{REF}/2 in a state in which SW₁ is turned off, SW₁₁ is turned on, and SW₁₂ is turned off. When the comparison is completed, voltage is stored in capacitor C₁ with SW₁₂ on and SW₁₃ off, and is delivered as input of a next step. Sequential conversion is performed up to the LSB by repeating the same sequence.

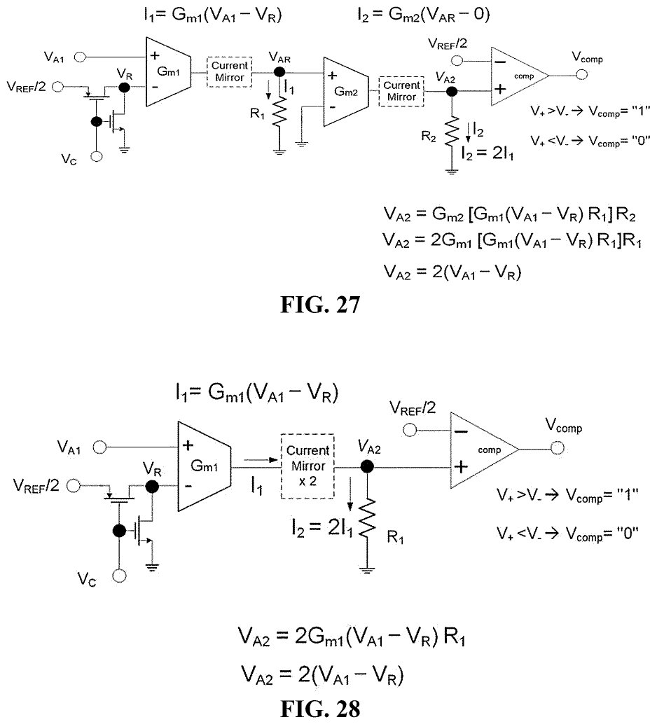

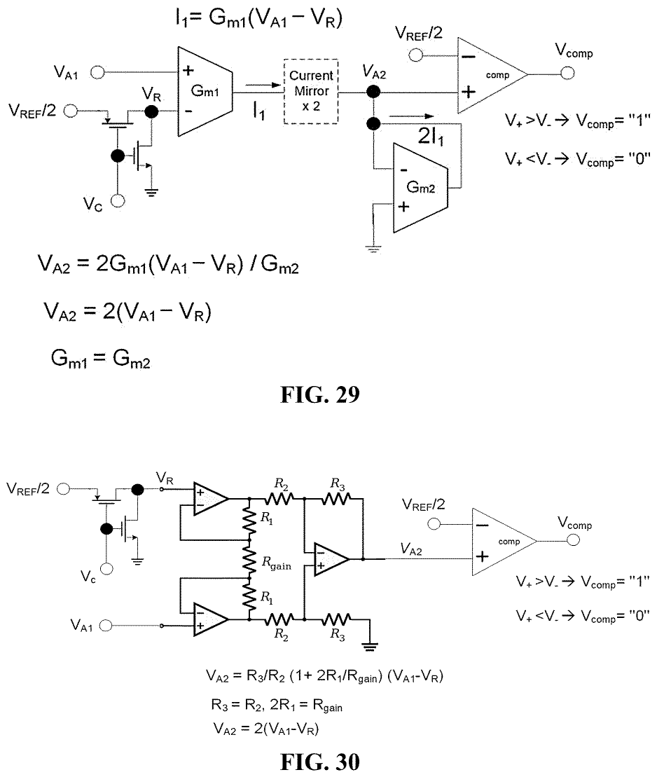

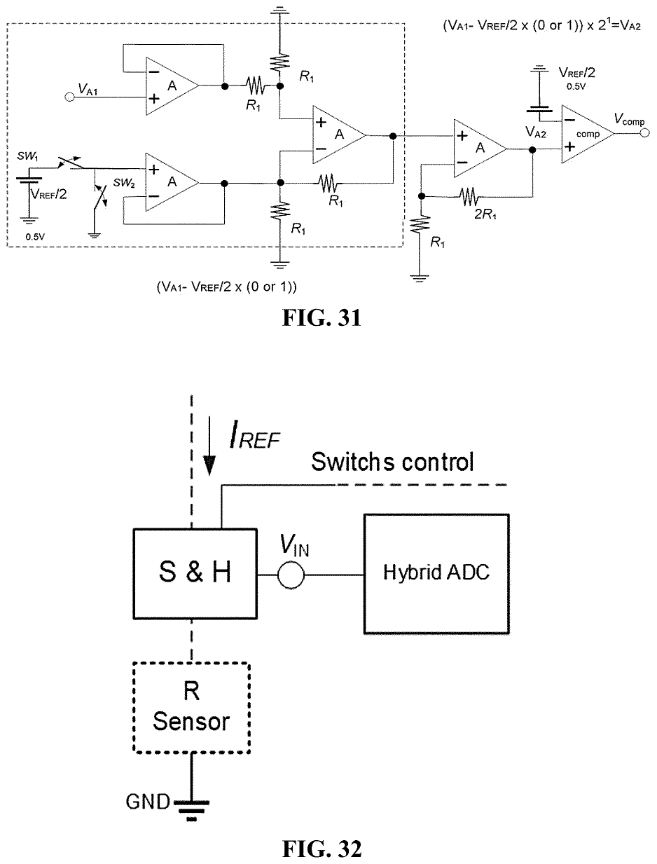

FIGS. 26 to 31 illustrate implementation examples of the input signal voltage generation circuit of FIG. 18. FIG. 26 illustrates an example of using two OTAs, FIGS. 27 and 28 illustrate an example of using two OTAs and a current mirror, FIG. 29 illustrates an example of using a single OTA, a current mirror, and an OTA-resistor combination, FIG. 30 illustrates an example of using an OP amplifier-based instrumentational amplifier, and FIG. 31 illustrates an example of using an OP amplifier buffer and a differential amplifier. These circuits may be implemented using an OP amplifier or an OTA, and the OTA method has a relatively low design difficulty.

A switching operation subtracts V_{REF}/2 from the input when SW₁ is turned on and SW₂ is turned off, and applies 0V when SW₁ is turned off and SW₂ is turned on. Then, the result voltage is doubled to form input of the next step.

The parallel hybrid ADC may be implemented by Combining the above voltage generation block with n comparators and the control logic, and may be expanded to group-parallel, cyclic, and parallel-cyclic combined structures. The reference voltage is controlled in real time by current source-resistor or capacitor-based DAC, and input transformation avoids generating the ultra-small reference voltage by repeatedly applying (V_{A}−V_{J})×2^{K} or (V_{An}−V_{REF}/2× (0 or 1))×2.

FIG. 19 is a configuration diagram that combines the parallel hybrid ADC of FIG. 2 and the cyclic hybrid ADC of FIG. 15. By combining the parallel section and the cyclic section, a high-speed operation, low power consumption, and a small area may be simultaneously achieved. By reducing the number of comparators and reference voltage generation circuits, the high speed and the high resolution may be secured while reducing the circuit complexity.

When the above structure is applied, the present invention achieves a higher speed than the SAR method and achieves the same level of resolution with a smaller number of comparators than the flash method. The internal operation may asynchronously proceed, thereby enabling operation without an external clock. Parallel, cyclic, and combined structures may be selected depending on required resolution and power/speed conditions for communication and sensor data processing and artificial intelligence (AI) computation.

Also, included is parallel group hybrid configuration that divides the comparator into a plurality of groups (see FIG. 12). The entire N bits are divided into a plurality of groups, each group performs parallel hybrid conversion, and a residual signal of an upper group is amplified and supplied as input of a lower group, thereby realizing ultra-high resolution. FIG. 8 illustrates an example of implementing 8 bits into three groups, 4 bits, 2 bits, and 2 bits, and FIGS. 20 to 23 illustrate examples of circuits based on the OP amplifier, the OTA, and the current mirror for converting the result of the upper group to input of the lower group.

In cyclic implementation, each bit is sequentially determined by updating the input voltage in a stepwise manner while fixing the reference voltage to ½ V_{REF} using a single comparator or a small number of comparators (see FIG. 15). After determining the MSB, a procedure of subtracting a value corresponding to a half of V_{REF} from the input and generating input of the next step by applying a multiplier is repeated. FIGS. 16 and 17 illustrate a step-by-step voltage update process for example input. The cyclic structure enables high-resolution conversion while minimizing hardware resources, but the conversion time may be longer than that of the parallel structure. If necessary, a structure that compromises parallel and cyclic may also be selected (see FIG. 19).

The reference voltage generation circuit may be implemented using a current-based method, a resistive voltage division method, and a capacitor method (see FIGS. 3 to 5). The current-based method is advantageous for continuous control, the resistive voltage division method provides a simple structures, and the capacitor method provides high accuracy. The methods may be applied alone or in combination depending on application.

If the number of comparators is set to N, they operate in a parallel hybrid mode as in FIG. 2. If the number of comparators is reduced and input update is repeated, they operate in a serial mode, and if a group is set, they operate in a parallel-group mode. The flowchart of FIG. 11 shows control flow in which the result of each comparison is immediately reflected in next step stetting in the parallel hybrid mode.

The sensor signal processing device proposed herein includes the hybrid ADC and converts analog output of a sensor to a fast and high-speed and high-precision digital code. Since a voltage formed in a sensor interface is directly applied to the ADC, pulse transformation and measurement steps are unnecessary, which minimizes delay. The sensor signal processing device includes a reference current source and a sample-and-hold circuit and suppresses current fluctuation and input fluctuation due to the environmental change, and provides a stable voltage. The sensor signal processing device is configured with the hybrid ADC including a sensor element, a reference current source, a sample-and-hold circuit, a plurality of comparators, and a control logic. Based on the comparison result, the reference voltage is adjusted in real time or input is updated to complete conversion in units of bit or bit group. Therefore, real-time high-speed conversion may be performed even under low power consumption conditions in various application, such as industrial use, medical use, and Internet of things (IoT).

Hereinafter, the sensor signal processing device that integrates the sensor and the ADC is described with reference to FIGS. 32 to 45.

FIG. 32 illustrates a basic block diagram in which a resistive sensor and a hybrid ADC are connected. Resistance of the resistive sensor changes depending on physical quantity, such as pressure, strain, and temperature, and stable reference current I_{REF} is applied to generate the voltage V_{IN}. I_{REF} is maintained to minimize the effect of temperature, power fluctuation, and noise, making it a key factor in conversion accuracy. The generated voltage V_{IN} is input to a sample-and-hold circuit that operates as a switch control signal, charges the capacitor in sample phase, and is maintained in hold phase. The maintained voltage is transmitted to the hybrid ADC and converted to a digital code. This configuration stabilizes the input voltage until just before conversion, thereby reducing errors.

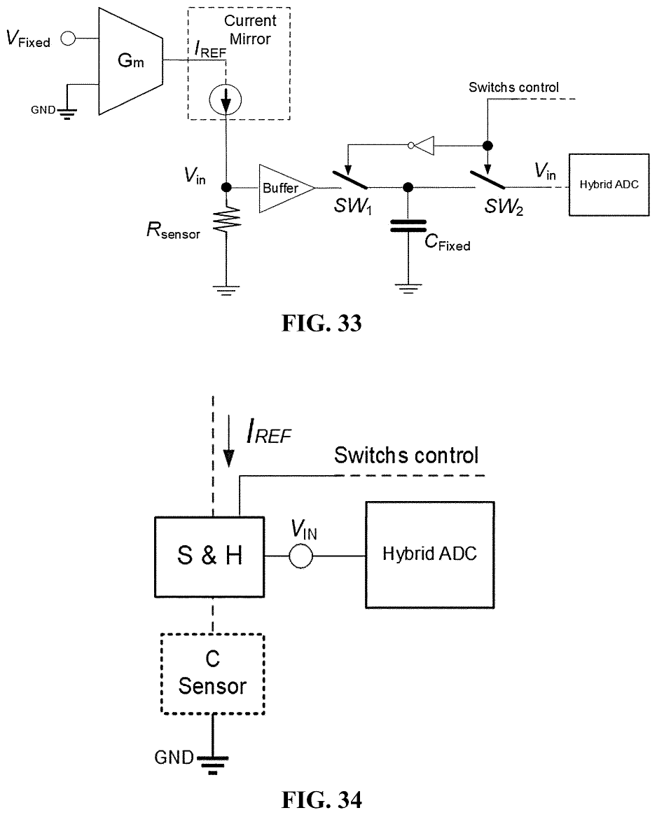

FIG. 33 implements the block configuration of FIG. 32 at the circuit level in detail. The circuit of this example embodiment may be configured such that a signal may be transmitted in the order of resistive sensor (Rₛₑₙₛₒᵣ)-reference current source (I_{REF})-buffer-sample-and-hold (S&H) capacitor (C_{Fixed})-switch (SW₂)-hybrid ADC. Gm (operational transconductance amplifier) on the left drives the current mirror with the reference voltage V_{Fixed}, and the mirror output supplies I_{REF} that is insensitive to temperature and power fluctuation to a top-end node of the sensor. Since a lower end of the sensor is fixed to the ground, the voltage of the top-end node is ideally Vᵢₙ≈I_{REF}×Rₛₑₙₛₒᵣ, and this voltage becomes the sensor output Vᵢₙ.

The sensor output is electrically separated from the S&H step through a buffer with voltage gain of 1. This may prevent kickback, sampling glitch, and load fluctuation occurring during subsequent switching and ADC sampling from being fed back to the sensor.

Switching is controlled by a non-overlapping clock. In sample phase, SW₁ is turned on and SW₂ is turned off to charge the buffer output to C_{Fixed}, and the C_{Fixed} voltage tracks Vᵢₙ. The SW₁ path includes an auxiliary switch with a bootstrap and clamp function to minimize the change in on-resistance and suppress charge injection and clock feedthrough. In hold/transfer phase, SW₁ is first turned off to preserve the C_{Fixed} voltage and SW₂ is turned on to apply the same to input of the hybrid ADC. After conversion is completed, SW₂ is turned off and SW₁ is turned on again in a next cycle.

During design, I_{REF} is stabilized by mirror matching and Gm bias, and Rₛₑₙₛₒᵣ range and supply voltage are determined such that Vᵢₙ operates within the compliance range of the current source. C_{Fixed} is selected such that kT/C noise is less than the target LSB, and the buffer width and switch-on resistance are determined by considering τ=R_{out_buf}×C_{Fixed} such that sufficient charging is performed during a sample time Tₛ.

Through the configuration and sequence, the circuit of FIG. 33 may stably sample a resistive sensor signal and may precisely deliver the same to the hybrid ADC.

FIG. 34 is a block diagram illustrating a sensor signal processing configuration including a single capacitive sensor and a hybrid ADC. This configuration includes a reference current source (I_{REF}), a sample-and-hold (S&H), a capacitive sensor (C_{Sensor}), a switch controller, and a hybrid ADC. Capacitance of the sensor varies depending on the change in pressure, humidity, and displacement, and voltage Vᵢₙ is formed at both ends of the sensor due to I_{REF}. Vᵢₙ is maintained for a certain period of time by the S&H and then applied to the ADC according to a switch control signal to convert to digital.

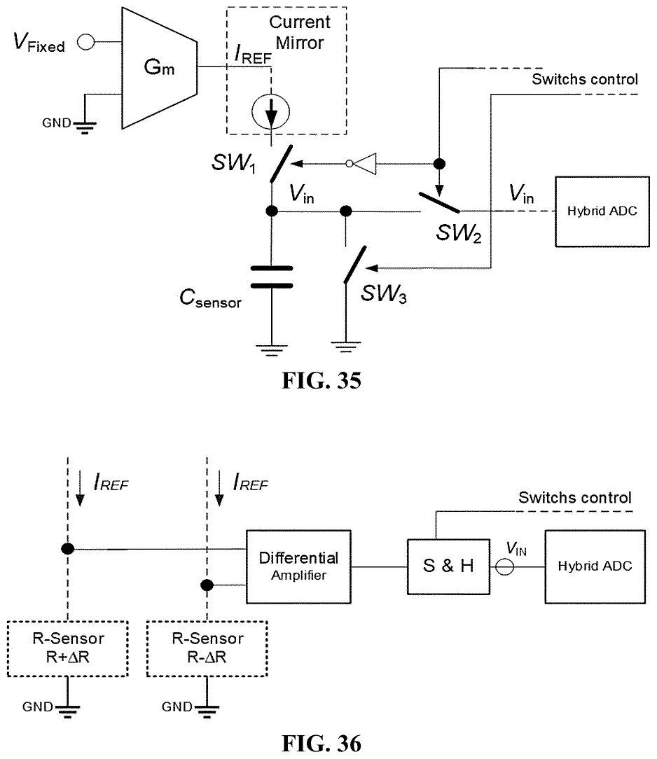

FIG. 35 illustrates the configuration of FIG. 34 at the circuit level in detail. The circuit is configured such that a signal is formed and transmitted in the order of Gm (operational transconductance amplifier)-current mirror-sensor capacitor (Cₛₑₙₛₒᵣ)-switches SW₁, SW₂, SW₃-hybrid ADC. Gm is biased by the reference voltage V_{Fixed} to drive the current mirror, and to stably output the reference current I_{REF} that is insensitive to the temperature and power fluctuation.

The operation proceeds in three steps according to non-overlapping control. In a sample step (SW₁=ON, SW₂=OFF, SW₃=OFF), I_{REF} is injected into a sensor node whereby C_{Sensor} is charged and the sensor node voltage Vᵢₙ is formed. If the charging time is fixed to Tₛ, ideally Vᵢₙ=(I_{REF}× Tₛ)/C_{Sensor}. A diode-type element of SW₂ input terminal serves as a clamp/bootstrap that suppresses reverse charge inflow during sampling. In a hold and transfer step (SW₁=OFF, SW₂=ON, SW₃=OFF), Vᵢₙ stored in Cₛₑₙₛₒᵣ is maintained and transferred to the hybrid ADC input through SW₂. Here, the sensor node is separated from a driving unit, so no feedback of ADC kickback occurs. In a reset step, initialization is performed by discharging the sensor node to the ground using SW₂=OFF and then SW₃=ON, and residual charge and ghost samples are prevented.

During design, Gm bias and current mirror matching may be set such that Vᵢₙ is formed within the compliance range of I_{REF}, and kT/C noise and settling time may be set to satisfy criteria at target resolution by considering Tₛ and switch on-resistance and C_{Sensor}. Through the above procedure, the change in capacity of C_{Sensor} may be converted to the stable voltage Vᵢₙ and may be accurately applied to the hybrid ADC.

FIG. 36 illustrates a sensor signal processing configuration connected to a hybrid ADC using a plurality of resistive sensors and a differential amplifier. This configuration includes two resistive sensors (R+ΔR, R−ΔR), reference current sources (I_{REF1}, I_{REF2}) that apply direct current (DC) reference current to the resistive sensors, respectively, a differential amplifier, a sample-and-hold (S&H) circuit, and a hybrid ADC. A lower end of each sensor is fixed to the ground, and an upper end thereof is connected in series to the corresponding reference current source. The reference current source is implemented as a current mirror or Gm-based circuit, and provides I_{REF} that is insensitive to process, temperature, and power fluctuation.

Here, the upper node voltage is defined as V_{P}=I_{REF1}×(R+ΔR), V_{N}=I_{REF2}× (R−ΔR). The differential amplifier generates single-ended output V_{OUT} by amplifying the differential voltage of two nodes (V_{P}, V_{N}), and sets the same as V_{OUT}=G×(V_{P}−V_{N}) for gain G. The common mode voltage of the amplifier is biased to match a downstream interface, and may include input protection and offset trimming if necessary. The S&H circuit charges V_{OUT} to a hold capacitor (C_{H}) in sample phase according to a switch control signal, maintains C_{H} voltage at V_{IN} in hold phase, and applies the same to input of the hybrid ADC.

If necessary, a reset path is included to discharge C_{H} to the reference voltage or the ground immediately prior to sampling. The hybrid ADC receives V_{IN} maintained in hold phase as input and performs conversion in a manner selected from among a parallel hybrid mode, a group hybrid mode, and a cyclic hybrid mode. That is, V_{P} and V_{N} are formed by applying I_{REF1} and I_{REF2}, V_{OUT} is generated using the differential amplifier, V_{IN} is sampled and maintained using the S&H, and conversion is performed using the ADC. The same function may be implemented as an equivalent circuit by one skilled in the art.

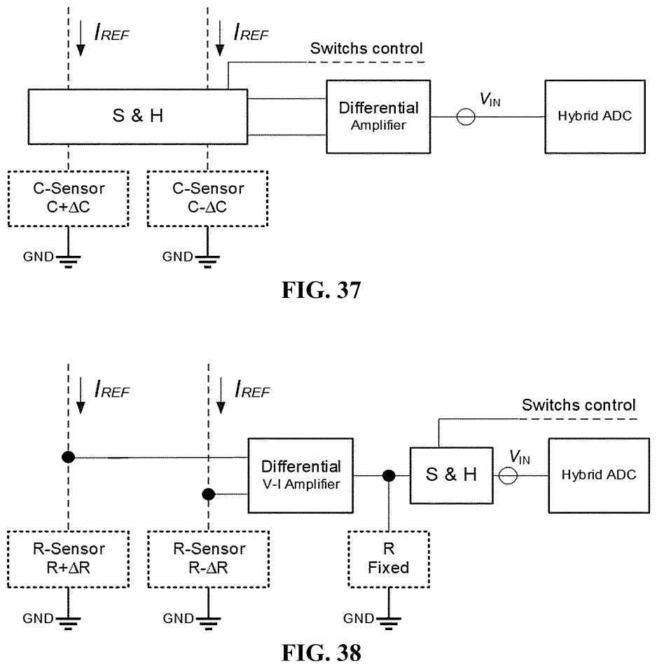

FIG. 37 illustrates a configuration connected to a hybrid ADC using a plurality of capacitive sensors and a differential amplifier. This configuration includes two capacitor sensors (C+ΔC, C−ΔC), two reference current sources that supply constant current to channels, respectively, S/H that may perform simultaneous sampling, a differential amplifier, and a hybrid ADC. One terminal of each sensor is connected to the ground, and the other terminal thereof is connected to an input node of the S/H, and independent I_{REF} is applied to each input node.

In sample phase, two channels are simultaneously sampled, I_{REF} is injected into a sensor node, and a sensor capacitor accumulates charge during time Tₛ. Here, V_{P}=I_{REF}×Tₛ/(C+ΔC) and V_{N}=I_{REF}×Tₛ/(C−ΔC) are formed, which may be sampled on hold capacitors (C_{H}+, C_{H}−) of S/H. In hold and transfer phase, a sample switch is blocked to maintain V_{P} and V_{N} of C_{H}+ and C_{H}−, which are applied to the differential amplifier. The amplifier amplifies difference between two voltages under common mode bias to gain G, and outputs single-ended V_{OUT}. That is, V_{OUT}=G× (V_{P}−V_{N}). V_{OUT} is input to the hybrid ADC as V_{IN}. If necessary, reset phase may be used to discharge the sensor node and C_{H} to the reference potential, and all timing is non-overlappingly controlled.

Two I_{REF} are supplied to the respective input nodes of S/H and returned to the ground through the sensors. Two hold nodes of S/H may be directly connected to positive input of the differential amplifier, and the amplifier output may be connected to V_{IN} without a buffer, if necessary. The reference current source is implemented as the current mirror or Gm-based circuit, and I_{REF} of two channels are set to the same value.

In short, after voltages formed during the same period of time by two sensors are simultaneously sampled, and converted to single-ended voltage through differential amplification, digital conversion is performed by the hybrid ADC.

FIG. 38 illustrates an example of generating an input signal voltage using an OTA and a fixed resistor in the configuration of FIG. 36. The same reference current I_{REF} is applied to upper ends of two resistive sensors (R+ΔR, R−ΔR), and lower ends thereof are connected to the ground. Therefore, V_{P}=I_{REF}×(R+ΔR) and V_{N}=I_{REF}×(R−ΔR) are formed, and two node voltages are applied to ±input of the OTA. The OTA outputs current I_{OUT}=gm×ΔV proportional to ΔV=V_{P}−V_{N}=2× I_{REF}×ΔR, and as this current flows through the fixed resistor R_{Fixed}, V_{O}=I_{OUT}×R_{Fixed}=gm× ΔV×R_{Fixed}. V_{O} is delivered to the S/H input, and the S/H output is directly connected to V_{IN} of the ADC.

The operation proceeds in non-overlapping timing of sample, hold, and reset. In sample phase, an S/H switch is turned on to charge V_{O} to the hold capacitor, V_{P} and V_{N} are maintained with I_{REF} of two sensors, and the OTA continuously provides I_{OUT} according to ΔV. In hold phase, the S/H input switch is turned off to maintain the storage voltage at V_{IN}, and the ADC performs conversion. If necessary, the reference potential is reset for a next cycle by providing a reset path to the S/H and OTA output nodes.

During design, two I_{REF} are generated to ensure the same current through the current mirror and the like, and common mode errors are suppressed by symmetrizing wiring and input leakage. The OTA is implemented in the differential input/single-ended output structure, and an output buffer is added if necessary. R_{Fixed} and gm are selected to satisfy the ADC input range and bandwidth conditions. As a result, the signal path is defined in the order of sensor (dual current drive)→differential V-I conversion (OTA)→I-V conversion through resistor→S/H→hybrid ADC.

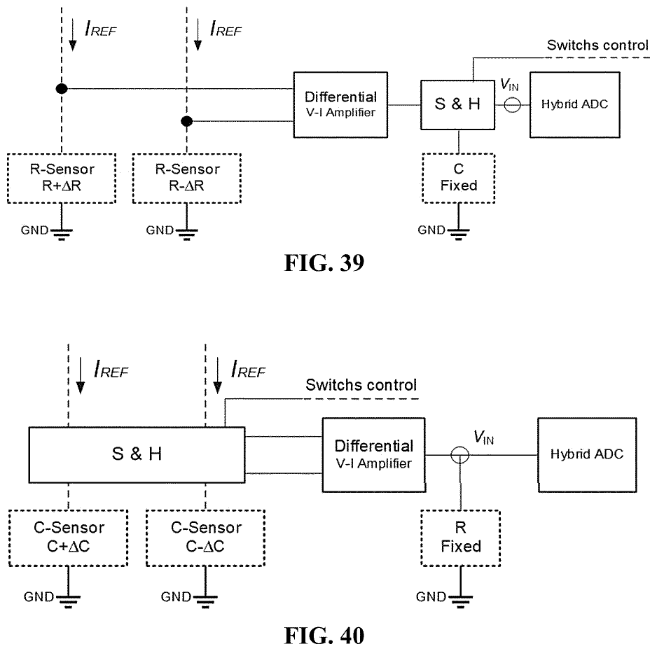

FIG. 39 illustrates an example of generating the input signal voltage using the OTA and the fixed capacitor in the configuration of FIG. 36. Upper ends of two resistive sensors (R+ΔR, R−ΔR) are applied with the same reference current I_{REF}, and lower ends thereof are connected to the ground. Therefore, V_{P}=I_{REF}×(R+ΔR) and V_{N}=I_{REF}×(R−ΔR) are formed, and two node voltages are applied to the differential input of the OTA. The OTA outputs the current I_{OUT}=gm× ΔV proportional to ΔV=V_{P}−V_{N}=2× I_{REF}×ΔR, and the output node is directly connected to the fixed capacitor C_{Fixed} for the ground.

I_{OUT} charges or discharges C_{Fixed} during an integration time T_{INT}, so V_{O} (t₀+T_{INT})=V₀(t₀)+ (I_{OUT}/C_{Fixed})× T_{INT}. If necessary, V₀(t₀) is initialized to 0 V or the common mode V_{CM} using the reset switch Φ_{R}. V_{O} is connected to the sample-and-hold (S/H) input. Under non-overlapping switch control, V_{O} is tracked and stored in the internal capacitor in integration/sample phase(s), and storage voltage is maintained at V_{IN} and delivered to the hybrid ADC in hold/conversion phase (PH). Optionally, in Φ_{R} phase, the next cycle is prepared by discharging C_{Fixed} and S/H internal capacitor.

During design, two I_{REF} ensure the same current using the current mirror of the common reference, and C_{Fixed}, T_{INT}, and gm are selected to satisfy the ADC input range and bandwidth. If necessary, a buffer may be inserted between the OTA output and the S/H or a damping element may be connected in parallel to an integration node to suppress ringing. As a result, the signal path is defined as sensor (dual current drive)→differential V-I conversion (OTA)→voltage generation through capacitor integration→S/H→hybrid ADC.

FIG. 40 illustrates an example of generating the input signal voltage using the OTA and the fixed resistor in the configuration of FIG. 37. Lower ends of two capacitor sensors (C+ΔC, C−ΔC) are connected to the common ground, and upper ends thereof are connected to the S&H input, and the same reference current I_{REF} is injected into each upper end. Two outputs of the S&H are applied to (+) and (−) input of the OTA, and single output of the OTA is connected to the fixed resistor R_{Fixed} for the ground. This resistive node voltage becomes V_{IN} and is transmitted to the hybrid ADC.

The operation includes three steps according to non-overlapping control.

First, in the reset (PR) step, the S&H hold capacitor is initialized to the common mode V_{CM}, and the sensor node is also pre-charged to V_{CM} or GND if necessary.

Second, in the charge and sample (Øs) step, I_{REF} is injected to the upper end of each sensor for time T_{CHG}, V_{P}=V_{CM}+ (I_{REF}/(C+ΔC))× T_{CHG} and V_{N}=V_{CM}+ (I_{REF}/(C−ΔC))× T_{CHG} are formed, and two voltages are sampled across the S&H hold capacitor. In small-signal approximation, ΔV=V_{P}−V_{N}≈(2×I_{REF}× T_{CHG}× AC)/C₂.

Third, in amplification and voltage conversion (PH) step, V_{P} and V_{N} maintained by S&H are applied to the OTA, OTA output current I_{OUT}=gm× ΔV is converted to the voltage through R_{Fixed} and V_{IN}=R_{Fixed}×I_{OUT}. If necessary, a buffer may be added to the V_{IN} node to block influence of change in ADC input impedance.

In short, the signal path includes differential capacitor sensor (dual current injection)→ simultaneous sampling by S&H→differential V-I conversion by OTA→generation of single voltage in R_{Fixed}→V_{IN}→hybrid ADC, and Φ_{R}-Φ_{S}-Φ_{H} timing forms stable V_{IN} while suppressing residual charge and charge injection.

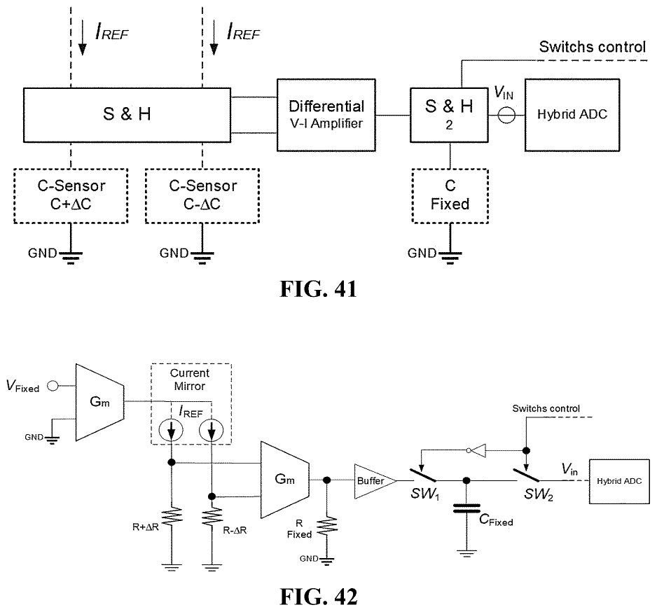

FIG. 41 illustrates an example embodiment of converting a differential voltage to current and then integrating the same to form a single-ended input voltage Vᵢₙ by adding an OTA, a rear-end S&H₂, and a fixed capacitor C_{Fixed} to the differential capacitive sensor interface. Lower ends of two sensors (C+ΔC, C−ΔC) are connected to the common ground and the same reference current I_{REF} is injected into upper ends thereof. An upper end node of the sensor is connected to front-end S&H and voltages of two nodes are sampled and maintained. Two outputs of the front-end S&H are applied as input of the OTA, and the OTA output is connected to a node in which a switch of S&H₂ and C_{Fixed} are juxtaposed. When the switch is on, I_{OUT} is integrated over C_{Fixed} to form a voltage. When the switch is off, a voltage thereof is held. This node voltage is V_{IN} and delivered to the hybrid ADC. The switch control is driven by a non-overlapping clock.

The operation sequence is as follows:

(1) Reset and pre-charge: The hold capacitor of front-end S&H is initialized to the common mode V_{CM}, and the upper end of the sensor is pre-charged to V_{CM} or GND if necessary. At the same time, C_{Fixed} is discharged through S&H₂.

(2) Sensor charging and sampling: I_{REF} injected during time T_{CHG} to form V_{P}=V_{CM}+ (I_{REF}/(C+ΔC))× T_{CHG} and V_{N}=V_{CM}+ (I_{REF}/(C−ΔC))× T_{CHG}, which are sampled and maintained by the front-end S&H. In small signal approximation, ΔV=V_{P}−V_{N}≈(2×I_{REF}× T_{CHG}× AC)/C₂.

(3) V-I conversion and integration: With the front-end S&H in a hold state, the OTA generates I_{OUT}=gm× ΔV. If the switch of S&H₂ is turned on and integrated over C_{Fixed}, V_{IN} (t)=(1/C_{Fixed})∫I_{OUT} dt, and an integration time is T_{INT}. When the start voltage is reset to 0, V_{IN}=(I_{OUT}/C_{Fixed})× T_{INT}.

(4) Hold and ADC application: After integration is completed, S&H₂ is turned off to hold the voltage and to apply V_{IN} to the ADC. If necessary, the buffer is inserted into the V_{IN} node to block load effect of the integration node.

In short, the signal path is defined as differential capacitor sensor (dual I_{REF} injection)→simultaneous sampling by front-end S&H→V-I conversion by OTA→C_{Fixed} integration and hold by S&H₂→V_{IN}→hybrid ADC. Separately operating the front-end S&H and the back-end S&H forms stable V_{IN} while suppressing charge injection and glitch.

FIG. 42 illustrates an example of implementing the path (differential resistive sensor→current-voltage conversion→S&H→hybrid ADC) of FIG. 38 at circuit level. The OTA (Gm₁) on the left is biased with the reference voltage V_{Fixed} to drive the current mirror, generates two paths of the same-sized reference current I_{REF} and supplies the same to each sensor branch. Lower ends of two resistive sensors (R+ΔR, R−ΔR) are connected to the common ground, and I_{REF} is injected into upper ends thereof to form V_{P}═I_{REF}×(R+ΔR) and V_{N}=I_{REF}×(R−ΔR). The differential voltage is ΔV=V_{P}−V_{N}=2×I_{REF}×ΔR.

Two upper end nodes are connected to the input of the second OTA (Gm₂), and Gm₂ outputs I_{OUT}=gm₂×ΔV. I_{OUT} is converted to the voltage V_{O}=I_{OUT}×R_{Fixed}=gm₂×ΔV×R_{Fixed} through the fixed resistor R_{Fixed} connected to the ground. The following buffer separates the V_{O} node with high impedance to prevent downstream switching load from affecting the leading edge.

The buffer output is input to S&H. The S&H includes SW₁ (sample switch), C_{Fixed} (hold capacitor), and SW₂ (transfer switch). In sample phase, SW₁ is turned on to charge C_{Fixed} with V_{O} and SW₂ is maintained to be off. In hold/transfer phase, SW₁ is turned off and SW₂ is turned on with a non-overlapping clock to apply the hold voltage to the ADC as the single-ended input V_{IN}. If necessary, a pre-charge section is provided to reset C_{Fixed} for next conversion.

Two I_{REF} paths are injected into the upper ends of the sensors with the same size and polarity, and the lower ends of the sensors are fixed to the common ground. An output node of Gm₂ is connected only to R_{Fixed} and S&H input (through buffer), and current-to-voltage conversion and sampling operation are clearly defined. The switch control relates to non-overlapping timing such that SW₁ and SW₂ do not simultaneously conduct, and is set to match ADC sampling timing.

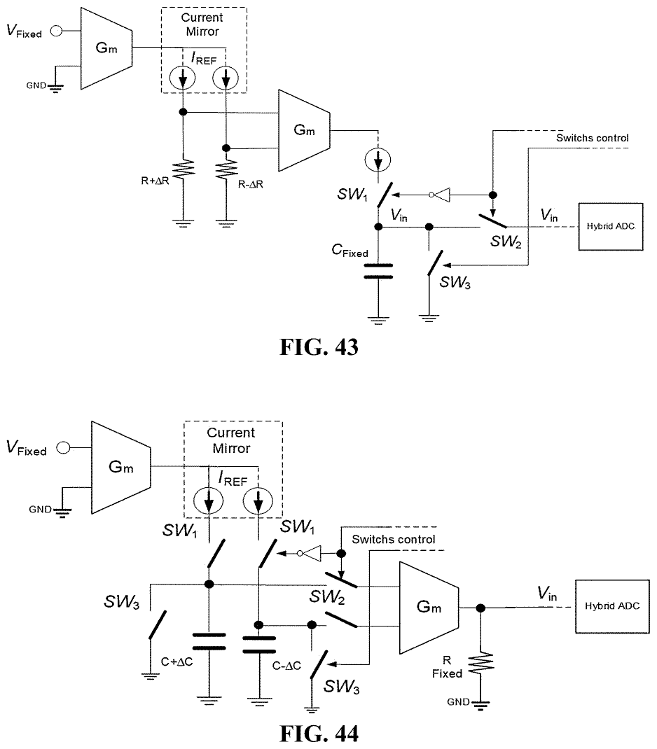

FIG. 43 is a circuit diagram that details the configuration of FIG. 39 to the transistor level, and illustrates an example of generating a micro change (+ΔR) of the differential resistive sensor as a single-ended input voltage V_{IN} through Gm (OTA), a current mirror, and a current-integration S&H, and providing the same to the hybrid ADC. Gm on the left is biased with the reference voltage V_{Fixed} to drive the current mirror, and generates two paths of the same-sized reference current I_{REF} and supplies the same to each sensor branch. Lower ends of two resistive sensors (R+ΔR, R−ΔR) are connected to the common ground, and I_{REF} is injected into upper ends thereof to form V_{P}═I_{REF}×(R+ΔR) and V_{N}=I_{REF}×(R−ΔR). The differential voltage is defined as ΔV=2× I_{REF}×ΔR.

Two upper end nodes are connected to the input of the second Gm (differential input, single current output), and Gm outputs I_{OUT}=gm× ΔV. This current flows in the integration node Vᵢₙ of S&H and is integrated across the fixed capacitor C_{Fixed} connected to the ground. The S&H includes three switches SW₁ (integration), SW₂ (transfer), and SW₃ (reset), and operates under non-overlapping switch control. In reset step (PRST), SW₃ is turned on, and SW₁ and SW₂ are turned off to discharge C_{Fixed} and to initialize the same to Vᵢₙ=0.

In sample/integration step(s), SW₁ is turned on, and SW₂ and SW₃ are turned off whereby I_{OUT} flows in C_{Fixed} for set time Tᵢₙₜ and Vᵢₙ (t)=(1/C_{Fixed})∫I_{OUT} dt˜ (I_{OUT}×Tᵢₙₜ)/C_{Fixed} (constant current approximation). In hold/transfer step (Φ_{H}), SW₁ is non-overlappingly turned off and then, SW₂ is turned on to output Vᵢₙ stored in C_{Fixed} to the single-ended V_{IN}, and the hybrid ADC performs conversion. After conversion, SW₂ is turned off and returns to reset for a next cycle.

Diode between the Vᵢₙ node and SW₂ indicates an optional clamp (or bootstrap) element for switch charge injection and kickback suppression. Two outputs of the current mirror are connected to upper end nodes of R+ΔR and R−ΔR, respectively, and lower ends of two sensors are fixed to the common ground. The single current output of the second Gm is connected only to the SW₁ input of S&H, and C_{Fixed} needs to be provided between Vᵢₙ and GND. The input of the hybrid ADC is single-ended and connected to the V_{IN} node behind SW₂ (when using the differential ADC, complementary terminal may be fixed to the reference potential or equivalent implementation may be performed using a separate buffer). Through the above configuration, FIG. 43 discloses a procedure of forming stable V_{IN} proportional to ΔR using the current integral S&H and non-overlapping switching and accurately applying the same to the hybrid ADC.

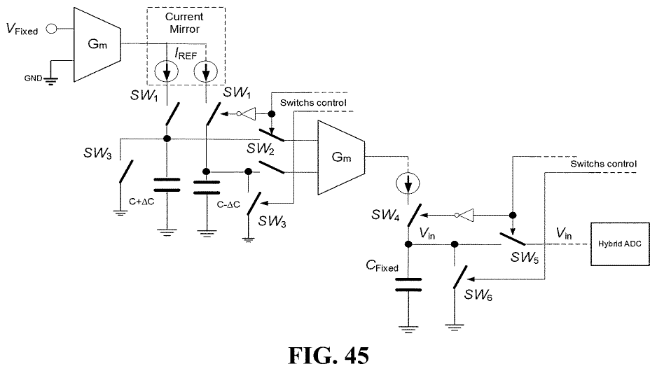

FIG. 44 illustrates an example of implementing the block configuration of FIG. 40 at the circuit level, and illustrates a process of generating the hybrid ADC input voltage V_{IN} by processing the change in electrostatic capacity (±ΔC) of the differential capacitive sensor in order of constant current charging, sample-and-hold, differential current conversion, and resistance voltage conversion.

The transconductance amplifier (Gm) on the left is biased with reference voltage V_{Fixed} to drive the current mirror and provides two paths of same sized reference current I_{REF}. The paths of I_{REF} are applied to upper end nodes of sensor capacitors C+ΔC and C−ΔC, respectively, through the upper switch SW₁, and lower ends thereof are connected to the common ground. The discharge switch SW₃ is provided to each upper end node and clamped to the ground upon reset.

In sample phase, SW₁=ON, SW₂=OFF, and SW₃=OFF are set such that I_{REF} flow in two capacitors for a certain time T_{CH}. Here, V_{P}=(I_{REF}×T_{CH})/(C+ΔC) and V_{N}=(I_{REF}×T_{CH})/(C−ΔC) are formed, and the differential voltage is approximated to ΔV=V_{P}−V_{N}≈(2× I_{REF}× T_{CH}÷C²)×ΔC(|ΔC|<<C assumption). The switch controller is driven by non-overlapping timing. When sampling is completed, SW₁ is non-overlappingly turned off to hold charge and if necessary, the clamp or bootstrap element is provided at the front end of SW₂ to suppress charge injection.

In transfer phase, SW₂=ON, V_{P} and V_{N} are connected to the input of differential Gm, and SW₃ is maintained to be turned off. The differential Gm generates the output current I_{OUT}=gm×ΔV proportional to ΔV, and this current is volt-ized through the fixed resistor R_{Fixed} connected to the ground, so Vᵢₙ=gm× R_{Fixed}×ΔV. Vᵢₙ is directly applied to the single-ended input V_{IN} of the hybrid ADC.

After conversion, SW₂=OFF, and in reset phase, SW₃=ON is set to discharge two sensor nodes and then, the next cycle starts in order of SW₃=OFF and SW₁=ON. Two outputs of the current mirror are connected to two upper end nodes behind SW₁, respectively. The two upper end nodes are connected to the input of the differential Gm through SW₂. The single current output of Gm is directly connected to R_{Fixed}, and the contact is Vᵢₙ. All switches are non-overlappingly driven, and SW₃ conducts only upon reset.

In short, FIG. 44 discloses a circuit and operation procedure of sampling ΔC to ΔV through the constant current charging sample-and-hold and then, forming the single-ended V_{IN} with the differential Gm and R_{Fixed} and stably transmitting the same to the hybrid ADC.

FIG. 45 illustrates an example of implementing the block configuration of FIG. 41 at the circuit level, and illustrates a two-step sampling structure that includes differential capacitor sensor→first sample-and-hold (S&H₁)→voltage-to-current converter (OTA, hereinafter, Gm)→second sample-and-hold (S&H₂)→hybrid ADC.

Gm on the left is biased with the reference voltage V_{Fixed} to drive the current mirror, and provides two paths of the same-sized reference current I_{REF}. Each I_{REF} is applied to upper end nodes of sensor capacitors C+ΔC and C−ΔC through the upper switch SW₁, and lower ends thereof are connected to the common ground. SW₃ for reset is provided to each upper end node. Each of the two sensor nodes is connected to the input of the differential Gm through the transfer switch SW₂. The single current output of the different Gm is transferred to S&H₂, and S&H₂ includes SW₄-C_{Fixed}-SW₆ and is connected to the ADC input V_{IN} through SW₅. All switches are driven with non-overlapping timing.

In resect phase, S&H₁ discharges the sensor node with SW₃=ON, SW₁=OFF, and SW₂=OFF. S&H₂ discharges C_{Fixed} with SW₆=ON, SW₄=OFF, and SW₅=OFF.

In S&H₁ sampling phase, SW₁=ON, SW₃=OFF, and SW₂=OFF are set to form upper end node voltages of two sensors for charging time T_{ch1}. V_{P}=(I_{REF}×T_{ch1})/(C+ΔC), V_{N}=(I_{REF}×T_{ch1})/(C−ΔC), and differential voltage ΔV=V_{P}−V_{N} are proportional to sensor AC.

In S&H₁ hold and transfer phase, SW₁ is non-overlappingly turned off and then, SW₂=ON is set to apply V_{P} and V_{N} to the differential Gm. The differential Gm generates the output current I_{OUT1}=gm₁×ΔV proportional to ΔV.

In S&H₂ sample (integration) phase, SW₄=ON, SW₆=OFF, and SW₅=OFF are set to integrate I_{OUT1} into C_{Fixed}, V_{BUF}=(I_{OUT1}×T_{ch2})/C_{Fixed} is formed and SW₄=OFF is held.

In ADC application phase, SW₅=ON is set to apply V_{BUF} to V_{IN} and to perform conversion. Here, S&H₁ and S&H₂ are maintained in a hold state such that ADC kickback does not affect the front end. After conversion, SW₅=OFF, SW₆=ON, and SW₃=ON are set to discharge each of C_{Fixed} and the sensor node, and the next cycle is prepared. SW₁↔SW₂ and SW₄↔SW₅ need to be non-overlappingly switched. S&H₁ operates as a differential voltage sampler, and S&H₂ operates as a single-ended voltage holder. Two branches of the current mirror are matched to provide the same I_{REF}, and SW₃ conducts only upon reset.

The above sensor signal processing device generates stabilized I_{REF} with Gm/current mirror, isolates and holds V_{IN} formed in the sensor with the buffer and S&H, and then directly supplies the same to the hybrid ADC (including control logic, comparator array, and resistor/current/capacitor-based DAC) to digitally convert the voltage. The switch is driven by non-overlapping timing and dedicated reset path, and suppresses charge injection and kickback. The resistive, capacitive/differential sensors may be processed in the same framework, and direct conversion is enabled without pulse width conversion or external counter. This hybrid ADC may simultaneously satisfy high-speed/high-resolution/low-power requirements by selecting or mixing parallel, group division, and cyclic modes, and may secure immunity to the change in temperature and power and noise through reference current stabilization and S&H isolation.

In this specification (particularly, in the claims), the above or similar referential terms may include both singular and plural forms depending on the context. When the numerical range is stated, it may be interpreted to include each individual value within the range unless specified otherwise. The steps of the method may be performed in any suitable order unless there is an explicit order requirement and may not be limited to the stated order. The described example embodiments are merely illustrative examples for description and should not be interpreted to limit the scope of the claims. It will be apparent to those skilled in the art that various modifications, combinations, and alterations may be made thereto without departing from the spirit and scope of the claims and their equivalents.

Therefore, the scope of the present invention may be defined by the claims and their equivalents.

What is claimed is:

1. A hybrid analog-to-digital converter device for generating N-bit digital output (N≥1, natural number), the hybrid analog-to-digital converter device comprising:
a control-logic circuit;
n comparators (n≥1, natural number) each configured to compare an input signal voltage (V_{A}) and a reference voltage and to generate comparison output; and
a reference voltage generation circuit configured to provide the preset reference voltage to the comparator,
wherein the control-logic circuit controls the reference voltage generation circuit according to the comparison output of the comparator to adjust the reference voltage or the input signal voltage (V_{A}) that is applied to a single comparator or applied to at least one comparator among a plurality of comparators.

2. The hybrid analog-to-digital converter device of claim 1, wherein the n comparators include a first comparator to an n^{th} comparator (Lₙ) that compare the input signal voltage (V_{A}) and the reference voltage and generate the comparison output,
the control-logic circuit controls the reference voltage of a lower bit comparator according to the comparison output of an upper bit, and
the number of the n comparators, n, is set to be the same as the number of output bits, M.

3. The hybrid analog-to-digital converter device of claim 1, wherein at least one comparator among the comparators is provided with the reference voltage corresponding to a ½ value of a maximum reference voltage (V_{REF}), and the input signal voltage is transformed in a stepwise manner and repeatedly compared over a plurality of comparison steps.

4. The hybrid analog-to-digital converter device of claim 3, wherein, to determine a most significant bit (MSB), the control-logic circuit generates an input signal voltage of a next step by comparing the input signal voltage with the ½ value of the maxim reference voltage (V_{REF}), by subtracting a portion of the ½ V_{REF} from the input signal voltage based on the MSB decision result, and by enlarging a remaining value by a predetermined ratio.

5. The hybrid analog-to-digital converter device of claim 1, wherein the reference voltage generation circuit includes at least one of:
a digital-to-analog conversion (DAC) circuit that includes at least one of a resistive element and a capacitor element based on current;
a circuit configured to generate the reference voltage based on a reference current source and a variable resistive element;
a circuit configured to generate a plurality of reference voltages using resistive voltage division elements; and
a circuit configured to generate the reference voltage using charging or discharging of a capacitor.

6. The hybrid analog-to-digital converter device of claim 1, wherein the comparators are configured with a plurality of groups,
each group corresponds to some bits of the N-bit digital output, and
the control-logic circuit controls the sequential conversion for the plurality of groups by determining the analog input signal voltage of a second group based on the comparison result of a first group and by determining the analog input signal voltage of a third group based on the comparison result of the second group, and generates an input signal voltage of the second group by multiplying a difference acquired by subtracting a least significant bit reference voltage value of the first group from the input signal voltage of the first group by a constant multiplier determined according to the comparison result of the first group.

7. A hybrid analog-to-digital conversion method for acquiring N-bit digital output (N≥1, natural number), the method comprising:
generating at least one comparison result by comparing an analog input signal voltage with at least one reference voltage using n comparators (n≥1, natural number);
adjusting the reference voltage or the analog input signal voltage through a control-logic circuit based on the comparison result; and
determining each bit of the N-bit digital output by repeatedly performing the generating of the comparison result and the adjusting over a plurality of conversion steps for determining an output bit, or by repeatedly performing the same based on a conversion group unit that groups a plurality of bits into a single group.

8. The method of claim 7, further comprising:
dividing an analog input signal into a plurality of groups of bit sets and processing the same, and adjusting the analog input signal of a lower group according to the conversion result of an upper group,
wherein one of the at least one reference voltage used in the generating of the comparison result is fixed to ½ of the maximum reference voltage (V_{REF}), and
the adjusting comprises generating the N-bit digital output by changing the analog input signal voltage at each comparison step.

9. The method of claim 7, further comprising:
sampling and maintaining an analog signal proportional to output of a sensor element and providing the same as the analog input signal voltage, prior to the generating of the comparison result.

10. A sensor signal processing device comprising:
a sensor element of which an electrical characteristic changes according to physical quantity;
a reference current source configured to generate an analog input signal voltage corresponding to output of the sensor element by applying reference current to the sensor element;
a sample-and-hold circuit configured to sample and hold the analog input signal voltage; and
a hybrid analog-to-digital converter (ADC) configured to generate N-bit digital output (N≥1, natural number) by repeatedly comparing the analog input signal voltage using n comparators (n≥1, natural number) and a control-logic circuit.

11. The sensor signal processing device of claim 10, wherein the sensor element is a resistive sensor or a capacitor sensor, and
the reference current source generates the analog input signal voltage by applying, to the sensor element, reference current that is not affected by change in an electrical characteristic according to change in an environmental condition.

12. The sensor signal processing device of claim 10, wherein the sensor element includes a first sensor and a second sensor that are differentially connected,
the sensor signal processing device forms two analog voltages by applying the reference current to the first sensor and the second sensor through a first current source and a second current source, respectively, and generates the analog input signal voltage by amplifying a differential signal between the two voltages using a differential amplifier,
the reference current source is implemented using an operational transconductance amplifier (OTA) and a reference resistor, and
the sample-and-hold circuit maintains the analog input signal voltage within the reference error range by suppressing voltage fluctuation and noise during a conversion process.
